(19) United States
(12) Patent Application Publication
(10) Pub. No.: US 2025/0063831 A1
(43) Pub. Date: Feb. 20, 2025

(54) MULTILAYER PHOTOELECTRIC CONVERTER, MULTILAYER PHOTOELECTRIC CONVERTER ARRAY, NON-CONTACT TEMPERATURE MEASUREMENT DEVICE, AND IMAGING DEVICE

(71) Applicant: Panasonic Intellectual Property Management Co., Ltd., Osaka (JP)

(72) Inventors: Nozomu MATSUKAWA, Nara (JP); Sanshiro SHISHIDO, Osaka (JP)

(21) Appl. No.: 18/935,675

(22) Filed: Nov. 4, 2024

Related U.S. Application Data
(63) Continuation of application No. PCT/JP2023/017495, filed on May 10, 2023.

(30) Foreign Application Priority Data
May 24, 2022 (JP) 2022-084832

(51) Int. Cl. H01L 31/10; G01J 5/48; H01L 27/146; H01L 31/0224

(52) U.S. Cl. CPC H01L 31/10; G01J 5/48; H01L 27/14643; H01L 27/14665; H01L 31/022408

(57) ABSTRACT

A multilayer photoelectric converter includes a first photoelectric converter, and a second photoelectric converter. The first photoelectric converter and the second photoelectric converter are stacked in this order from a side of the multilayer photoelectric converter where light is incident. The first photoelectric converter has a sensitivity characteristic with a sensitivity having a peak at a wavelength λ1a. The second photoelectric converter has a sensitivity characteristic with a sensitivity having a peak at a wavelength λ2a. For the multilayer photoelectric converter, the relationship λ1a<λ2a is satisfied. The sensitivity of the second photoelectric converter at the wavelength λ2a is less than the sensitivity of the first photoelectric converter at the wavelength λ1a.

### BACKGROUND

### 1. Technical Field

The present disclosure relates to a multilayer photoelectric converter, a multilayer photoelectric converter array, a non-contact temperature measurement device, and an imaging device.

### 2. Description of the Related Art

In the related art, for non-contact measurement of the characteristics of a substance, light radiated or reflected by the substance is detected as a signal by a photoelectric converter or a photoelectric converter array.

If, for instance, the properties to be measured are the temperature of the substance and the ratio between the components of the substance, it may be required in some cases to detect different wavelengths of light. Exemplary methods for measuring the characteristics of a substance by detecting different wavelengths of light include a method of using photoelectric converters with different wavelength characteristics, and a method of switching optical filters to vary the wavelength of light to be transmitted. To measure the characteristics of a substance at the same location, sensors including a stack of photoelectric converters with different sensitivity characteristics have been proposed.

With a material used for the photoelectric conversion layer of a photoelectric converter, light with an energy exceeding the band gap of the material is absorbed, whereas light with an energy below the band gap of the material is transmitted. Accordingly, in stacking photoelectric converters, a photoelectric conversion layer including a material with large band gap is disposed near an area where light is incident. Low-energy light not absorbed by the material with large band gap, that is, light at wavelengths longer than those of the light absorbed by the material with large band gap, is transmitted through the photoelectric conversion layer with large band gap, and absorbed by a photoelectric conversion layer including a material with relatively small band gap. In this way, a different wavelength of light can be received by each of the stacked photoelectric converters.

For example, Japanese Patent No. 4842291 discloses a method in which quantum-dot detectors employing three-dimensional semiconductor quantum wells (semiconductor quantum dots) are stacked to detect multiple wavelengths of light.

Japanese Unexamined Patent Application Publication No. 2020-197450 discloses a three-dimensional semiconductor quantum well structure whose wavelength characteristics vary with applied voltage, and a method in which multiple wavelengths of light are detected by using variation of wavelength characteristics to thereby measure temperature.

Japanese Patent No. 6135240 discloses a method in which, in addition to stacking of three-dimensional semiconductor quantum wells, layers whose refractive indices vary with applied voltage are stacked to thereby form a resonator structure, and resonant wavelengths are switched to detect multiple wavelengths of light.

### SUMMARY

As in, for example, FIG. 21 and paragraph 0013 of Japanese Patent No. 4842291, the patent documents mentioned above disclose features including: the order of stacking based on the direction of light incidence and the relative magnitudes of the wavelengths to be absorbed by the photoelectric conversion layers; a technique for extracting signals corresponding to multiple wavelengths of light; and computation of temperature based on signals corresponding to multiple wavelengths of light. The patent documents mentioned above, however, disclose neither of the following features with regard to measurement of the characteristics of a substance through detection of multiple wavelengths of light: the appropriate relationship between the sensitivities of the photoelectric converters to be stacked; and the appropriate relationship between the wavelengths to be absorbed by the photoelectric converters.

In measuring the characteristics of a substance by using a natural light source, such as measuring the temperature of the substance from thermal radiation, or measuring the proportions of components such as moisture, sugars, or acids within a sealed heating process vessel by using thermal radiation as a light source, the characteristics of the light source are uncontrollable, which means that unless the characteristics of the photoelectric converters are set in an appropriate manner, it is not possible to obtain desired results with sufficient accuracy.

One non-limiting and exemplary embodiment provides, for example, a multilayer photoelectric converter that allows multiple wavelengths of light to be detected with improved accuracy.

In one general aspect, the techniques disclosed here feature a multilayer photoelectric converter including a first photoelectric converter, and a second photoelectric converter. The first photoelectric converter and the second photoelectric converter are stacked in this order from a side of the multilayer photoelectric converter where light is incident. The first photoelectric converter has a sensitivity characteristic with a sensitivity having a peak at a wavelength λ1a. The second photoelectric converter has a sensitivity characteristic with a sensitivity having a peak at a wavelength λ2a. A relationship λ1a<λ2a is satisfied. The sensitivity of the second photoelectric converter at the wavelength λ2a is less than the sensitivity of the first photoelectric converter at the wavelength λ1a.

The present disclosure allows multiple wavelengths of light to be detected with improved accuracy.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 schematically illustrates a configuration of a multilayer photoelectric converter according to Embodiment 1;

FIG. 2 schematically illustrates an example of the sensitivity characteristics of the multilayer photoelectric converter according to Embodiment 1;

FIG. 3A is a graph illustrating the relationship between the wavelength and radiant intensity of thermal radiation;

FIG. 3B is a graph illustrating in detail the relationship between the wavelength and radiant intensity of thermal radiation at 400 K;

FIG. 4A schematically illustrates an example of the sensitivity characteristic of a single photoelectric converter;

FIG. 4B schematically illustrates an example of the sensitivity characteristic of a single photoelectric converter;

FIG. 4C schematically illustrates an example of the sensitivity characteristic of a single photoelectric converter;

FIG. 5A illustrates the sensitivity characteristics of the multilayer photoelectric converter according to Embodiment 1;

FIG. 5B illustrates the sensitivity characteristics of the multilayer photoelectric converter according to Embodiment 1;

FIG. 6A illustrates the relationship between wavelengths in the sensitivity characteristics of the multilayer photoelectric converter according to Embodiment 1;

FIG. 6B illustrates the relationship between wavelengths in the sensitivity characteristics of the multilayer photoelectric converter according to Embodiment 1;

FIG. 7 schematically illustrates another example of the sensitivity characteristics of the multilayer photoelectric converter according to Embodiment 1;

FIG. 8 schematically illustrates a detailed configuration of the multilayer photoelectric converter according to Embodiment 1;

FIG. 9 is a schematic cross-sectional view of an example of the multilayer structure of the multilayer photoelectric converter according to Embodiment 1;

FIG. 10A is a schematic cross-sectional view of another example of the multilayer structure of the multilayer photoelectric converter according to Embodiment 1;

FIG. 10B is a schematic cross-sectional view of another example of the multilayer structure of the multilayer photoelectric converter according to Embodiment 1;

FIG. 11A is a schematic plan view of an example of the shape of the multilayer structure illustrated in FIG. 10A or 10B;

FIG. 11B is a schematic plan view of an example of the shape of the multilayer structure illustrated in FIG. 10A or 10B;

FIG. 11C is a schematic plan view of an example of the shape of the multilayer structure illustrated in FIG. 10A or 10B;

FIG. 12A is a schematic cross-sectional view of still another example of the multilayer structure of the multilayer photoelectric converter according to Embodiment 1;

FIG. 12B is a schematic cross-sectional view of still another example of the multilayer structure of the multilayer photoelectric converter according to Embodiment 1;

FIG. 13 is a schematic plan view of an example of the shape of the multilayer structure illustrated in FIG. 12A or 12B;

FIG. 14A schematically illustrates a configuration of a multilayer photoelectric converter according to Modification 1 of Embodiment 1;

FIG. 14B schematically illustrates a configuration of the multilayer photoelectric converter according to Modification 1 of Embodiment 1;

FIG. 15 schematically illustrates a configuration of a multilayer photoelectric converter according to Modification 2 of Embodiment 1;

FIG. 16 illustrates the relationship between the sensitivity characteristics of the multilayer photoelectric converter according to Modification 2 of Embodiment 1, and the cutoff wavelengths of long-pass filters;

FIG. 17 schematically illustrates a configuration of a multilayer photoelectric converter according to Modification 3 of Embodiment 1;

FIG. 18 is a block diagram illustrating a configuration of a non-contact temperature measurement device according to Embodiment 2;

FIG. 19 schematically illustrates a configuration of an imaging device according to Embodiment 3;

FIG. 20 schematically illustrates a configuration of a pixel array of the imaging device according to Embodiment 3; and

FIG. 21 illustrates the relationship between light incident on a multilayer photoelectric converter, the location of an incident surface, the location of a first photoelectric converter, and the location of a second photoelectric converter.

### DETAILED DESCRIPTIONS

### Overview of Present Disclosure

A multilayer photoelectric converter according to an aspect of the present disclosure includes a first photoelectric converter, and a second photoelectric converter. The first photoelectric converter and the second photoelectric converter are stacked in this order from a side of the multilayer photoelectric converter where light is incident. The first photoelectric converter has a sensitivity characteristic with a sensitivity having a peak at a wavelength λ1a. The second photoelectric converter has a sensitivity characteristic with a sensitivity having a peak at a wavelength λ2a. For the multilayer photoelectric converter, a relationship λ1a<λ2a is satisfied. The sensitivity of the second photoelectric converter at the wavelength λ2a is less than the sensitivity of the first photoelectric converter at the wavelength λ1a.

As a result, the second photoelectric converter has, at the peak wavelength λ2a longer than the wavelength λ1a, a sensitivity less than the sensitivity of the first photoelectric converter at the peak wavelength λ1a. As a result, for cases where light such as thermal radiation, whose intensity as a function of wavelength is uncontrollable and increases at longer wavelengths, is to be detected for purposes such as measurement of the characteristics of a substance, the second photoelectric converter, which performs photoelectric conversion on high-intensity, longer-wavelength light, has decreased sensitivity. This makes it possible to, for example, increase the signal output of the first photoelectric converter, which performs photoelectric conversion on low-intensity, shorter-wavelength light, while reducing saturation of the signal output of the second photoelectric converter, which performs photoelectric conversion on high-intensity, longer-wavelength light. As a result, multiple wavelengths of light can be detected with improved accuracy. This allows, for example, the characteristics of a substance such as temperature to be measured with improved accuracy.

In another exemplary aspect, in the sensitivity characteristic of the second photoelectric converter, the sensitivity of the second photoelectric converter may have a cutoff at a wavelength λ2c longer than the wavelength λ2a. In the sensitivity characteristic of the first photoelectric converter, the sensitivity of the first photoelectric converter may have a cutoff at a wavelength λ1c longer than the wavelength λ1a. A relationship λ1c<λ2c may be satisfied.

This configuration tends to result in decreased sensitivity of the first photoelectric converter at the wavelength λ2a. As a result, the signal output from the second photoelectric converter based on light with the wavelength λ2a becomes less likely to be buried in the signal output from the first photoelectric converter based on light with the wavelength λ2a. This allows for improved accuracy of separation between the signal output from the first photoelectric converter and the signal output from the second photoelectric converter.

In another exemplary aspect, in the sensitivity characteristic of the second photoelectric converter, at wavelengths shorter than the wavelength λ2a, the sensitivity of the second photoelectric converter may decrease relative to the sensitivity at the wavelength λ2a and exhibit a local minimum at a wavelength λ2m, and then at wavelengths shorter than the wavelength λ2m, the sensitivity of the second photoelectric converter may increase and, at a wavelength λ2b, become substantially equal to the sensitivity of the first photoelectric converter at the wavelength λ1a. For the multilayer photoelectric converter, a relationship λ2b<λ1a may be satisfied.

As a result, the signal output from the first photoelectric converter based on light with the wavelength λ1a becomes less likely to be buried in the signal output from the second photoelectric converter based on light with the wavelength λ1a. This allows for improved accuracy of separation between the signal output from the first photoelectric converter and the signal output from the second photoelectric converter.

In another exemplary aspect, for the multilayer photoelectric converter, a relationship (λ2b+λ2m)/2<λ1a<(λ2m+λ2a)/2 may be satisfied.

This configuration results in the wavelength λ1a being located in the vicinity of the wavelength λ2m at which the sensitivity of the second photoelectric converter has a local minimum. As a result, the signal output from the first photoelectric converter based on light with the wavelength λ1a becomes further less likely to be buried in the signal output from the second photoelectric converter based on light with the wavelength λ1a. This allows for further improved accuracy of separation between the signal output from the first photoelectric converter and the signal output from the second photoelectric converter.

In another exemplary aspect, in the sensitivity characteristic of the first photoelectric converter, the sensitivity of the first photoelectric converter may have a cutoff at a wavelength λ1c longer than the wavelength λ1a, and at wavelengths shorter than the wavelength λ1a, the sensitivity of the first photoelectric converter may decrease relative to the sensitivity at the wavelength λ1a and exhibit a local minimum at a wavelength λ1m, and then increase at wavelengths shorter than the wavelength λ1m.

This configuration allows the first photoelectric converter to perform photoelectric conversion on light at wavelengths shorter than the wavelength λ1m. As a result, for cases where light such as thermal radiation, whose intensity as a function of wavelength is uncontrollable and increases at longer wavelengths, is to be detected for purposes such as measurement of the characteristics of a substance, the first photoelectric converter, which performs photoelectric conversion on low-intensity, shorter-wavelength light, can be further increased in sensitivity.

In another exemplary aspect, each of the first photoelectric converter and the second photoelectric converter may be a photodiode or a photoconductor.

This configuration makes it possible to achieve a photodiode—or photoconductor-type multilayer photoelectric converter.

In another exemplary aspect, each of the first photoelectric converter and the second photoelectric converter may include: a first electrode from which a signal is to be output; a second electrode located opposite to the first electrode; and a photoelectric conversion layer located between the first electrode and the second electrode.

This configuration makes it possible to, for example, apply voltage to the photoelectric conversion layer by means of the electrodes that are located opposite to each other. This may facilitate signal readout.

In another exemplary aspect, the first photoelectric converter and the second photoelectric converter may share the second electrode.

This configuration allows for simplified structure of the multilayer photoelectric converter.

In another exemplary aspect, at least one of the first photoelectric converter or the second photoelectric converter may further include a buffer layer. The buffer layer may be located at least one of between the photoelectric conversion layer and the first electrode, or between the photoelectric conversion layer and the second electrode.

This configuration allows for smooth charge transfer between the photoelectric conversion layer, and the first electrode or the second electrode.

In another exemplary aspect, at least one of the first photoelectric converter or the second photoelectric converter may further include a charge blocking layer. The charge blocking layer may be located at least one of between the photoelectric conversion layer and the first electrode, or between the photoelectric conversion layer and the second electrode.

This configuration allows injection of charge from the first electrode or the second electrode to be reduced by means of the charge blocking layer. This makes it possible to reduce noise caused by dark current.

In another exemplary aspect, at least one of the first photoelectric converter or the second photoelectric converter may include a quantum dot.

This configuration makes it easier to increase the sensitivity peak wavelength of the photoelectric converter. This configuration also allows the sensitivity peak wavelength of the photoelectric converter to be adjusted by adjusting the material and particle size of the quantum dot.

In another exemplary aspect, the quantum dot may include at least one of a metal pnictide, a metal chalcogenide, a metal halide, or a metal chalcohalide.

This configuration allows the sensitivity peak wavelength of the photoelectric converter to be controlled over a wide range of wavelengths from the visible to the infrared.

In another exemplary aspect, the quantum dot may include the metal chalcogenide, and the metal chalcogenide may be PbS, PbSe, PbTe, CdS, CdSe, CdTe, or HgCdTe.

This configuration allows the sensitivity peak wavelength of the photoelectric converter to be controlled over a wide range of wavelengths from the visible to the infrared.

In another exemplary aspect, the first photoelectric converter and the second photoelectric converter may be stacked in spaced relation to each other, and the multilayer photoelectric converter may further include a retainer that retains a constant gap between the first photoelectric converter and the second photoelectric converter.

This configuration makes it possible to reduce occurrence, due to the gap between the first photoelectric converter and the second photoelectric converter, of non-uniformity resulting from optical interference.

In another exemplary aspect, the multilayer photoelectric converter may further include an adhesive that fills a space between the first photoelectric converter and the second photoelectric converter, and the adhesive may be transmissive of light at the wavelength λ2a.

This configuration allows the influence of reflection to be reduced by reducing the difference in refractive index between the region of the gap and the second photoelectric converter.

In another exemplary aspect, the multilayer photoelectric converter may further include a first long-pass filter located at a side of the first photoelectric converter where the light is incident, and the first long-pass filter may have a cutoff wavelength λcut1 shorter than the wavelength λ1a.

This configuration helps to ensure that, even in the presence of a light source other than the light to be detected such as thermal radiation, the first long-pass filter blocks, among the wavelengths of light that are incident on the multilayer photoelectric converter, wavelengths of light shorter than or equal to the cutoff wavelength λcut1. This allows for reduction of noise resulting from the light source.

In another exemplary aspect, the multilayer photoelectric converter may further include a second long-pass filter located between the first photoelectric converter and the second photoelectric converter, and the second long-pass filter may have a cutoff wavelength λcut2 longer than the wavelength λ1a and shorter than the wavelength λ2a.

This configuration allows the second long-pass filter to transmit light at wavelengths longer than or equal to the wavelength λ2a while blocking light at wavelengths shorter than or equal to the wavelength λ1a. This allows for improved accuracy of separation between the signal output from the first photoelectric converter and the second signal output from the second photoelectric converter.

A multilayer photoelectric converter array according to an aspect of the present disclosure includes a plurality of the multilayer photoelectric converters mentioned above. The multilayer photoelectric converters are arrayed one-dimensionally or two-dimensionally.

This configuration makes it possible to improve the accuracy of one-dimensional or two-dimensional measurement of the characteristics of a substance such as temperature.

A non-contact temperature measurement device according to an aspect of the present disclosure includes the multilayer photoelectric converter mentioned above, a signal detection circuit, and a computer. The signal detection circuit detects a first signal, and a second signal. The first signal is output from the first photoelectric converter. The second signal is output from the second photoelectric converter. The computer computes a temperature, based on the first signal and the second signal detected by the signal detection circuit.

This configuration allows a temperature to be computed through detection of thermal radiation by the multilayer photoelectric converter mentioned above. This makes it possible to improve the accuracy of non-contact temperature measurement.

An imaging device according to an aspect of the present disclosure is an imaging device that captures a temperature image. The imaging device includes the multilayer photoelectric converter array mentioned above, a signal detection circuit, and a computer. The signal detection circuit detects a first signal, and a second signal. The first signal is output from the first photoelectric converter of each of the multilayer photoelectric converters. The second signal us output from the second photoelectric converter of each of the multilayer photoelectric converters. The computer computes a temperature corresponding to an output of each of the multilayer photoelectric converters, based on the first signal and the second signal detected by the signal detection circuit.

This configuration allows an accurate temperature image to be captured by use of the multilayer photoelectric converter array mentioned above.

Embodiments of the present disclosure will be described below with reference to the drawings.

Embodiments described below each represent a generic or specific example. Specific details set forth in the following description of embodiments, such as numeric values, shapes, constituent elements, the positioning and connection of constituent elements, steps, and the order of steps, are for illustrative purposes only and not intended to limit the scope of the present disclosure. Those constituent elements in the following description of embodiments which are not cited in independent claims will be described as optional constituent elements. It is to be understood that the drawings are not necessarily precise illustrations. Accordingly, for example, the drawings are not necessarily consistent in details such as scale. Throughout the drawings, identical reference signs are used to designate substantially identical features, and repetitive descriptions will be sometimes omitted or simplified.

As used herein, terms indicative of the relationship between elements, terms indicative of a shape of an element, and numerical ranges are not intended to represent only their strict meanings but are meant to also include their substantial equivalents, for example, equivalents with deviations or differences of about a few percent.

As used herein, terms such as “above” and “below” do not refer to the upward direction (vertically above) and the downward direction (vertically below) in the sense of absolute spatial recognition, but are used as terms defined by relative positions of elements based on the order of their stacking within a multilayer structure. In the following description, “above”, “below”, and other similar terms are used solely to specify the relative positioning of components, and are not intended to limit how such components are oriented when a multilayer photoelectric converter, a multilayer photoelectric converter array, a non-contact temperature measurement device, and an imaging device are in use. Terms such as “above” and “below” are used not only for cases where two constituent elements are disposed in spaced relation to each other with another constituent element therebetween, but also for cases where two constituent elements are disposed in close contact with each other.

Herein, the entire range of electromagnetic radiation including visible light, infrared radiation, and ultraviolet radiation is referred to as “light” for convenience.

As used herein without particular specification or designation, the term “sensitivity” refers to the effective sensitivity after photoelectric converters or other constituent elements have been incorporated.

As used herein without particular specification or designation, the term “peak” refers to, among one or more local maxima in sensitivity that are present, the local maximum at the longest wavelength.

Herein, the wavelength at which a photoelectric converter substantially loses, for example, its sensitivity or transmittance is expressed as “cutoff” for convenience.

### EMBODIMENT 1

### General Configuration

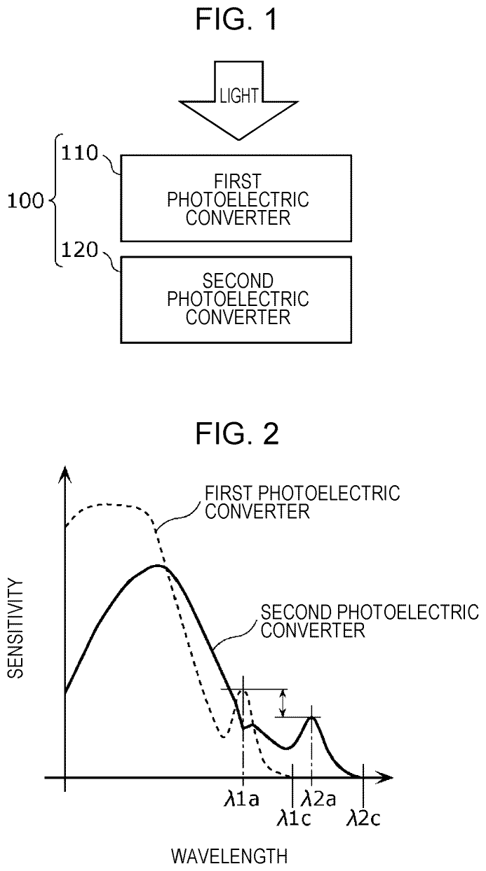

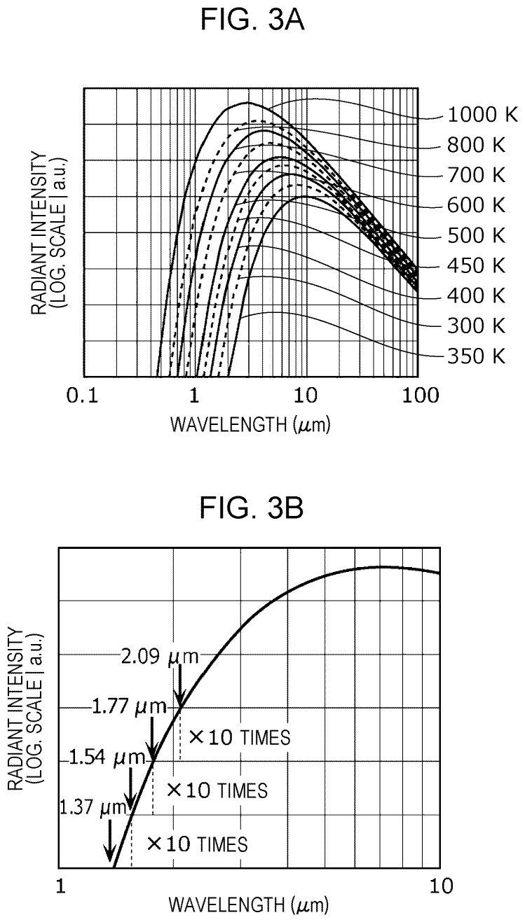

First, a general configuration of a multilayer photoelectric converter according to Embodiment 1 is described. FIG. 1 schematically illustrates a configuration of a multilayer photoelectric converter 100 according to Embodiment 1. FIG. 2 schematically illustrates an example of the sensitivity characteristics of the multilayer photoelectric converter 100. FIG. 2 illustrates the wavelength dependence of the sensitivity of the multilayer photoelectric converter 100. In FIG. 2, the vertical axis represents sensitivity, and the horizontal axis represents wavelength. Sensitivity represents, for example, the quantum efficiency of the photoelectric converter. FIG. 3A is a graph illustrating the relationship between the wavelength and radiant intensity of thermal radiation. FIG. 3A illustrates the relationship between the wavelength and radiant intensity of block body radiation at temperatures from 300 K to 1000 K. FIG. 3B is a graph illustrating in detail the relationship between the wavelength and radiant intensity of thermal radiation at 400K. FIG. 3B illustrates, in enlarged scale, the relationship between the wavelength and radiant intensity of block body radiation at 400 K illustrated in FIG. 3A.

As illustrated in FIG. 1, the multilayer photoelectric converter 100 includes a first photoelectric converter 110, and a second photoelectric converter 120. The first photoelectric converter 110 and the second photoelectric converter 120 of the multilayer photoelectric converter 100 each output a signal corresponding to the amount of light incident thereon.

The first photoelectric converter 110 and the second photoelectric converter 120 are stacked in this order from an incident side, which is a side of the multilayer photoelectric converter 100 where light is incident. That is, the first photoelectric converter 110 is located closer to the incident side than is the second photoelectric converter 120. The first photoelectric converter 110 and the second photoelectric converter 120 are arranged in this order in a direction in which light travels after incidence on the multilayer photoelectric converter 100. The multilayer photoelectric converter 100 is configured to allow the incoming light from the incident side to be received by the first photoelectric converter 110 and the second photoelectric converter 120. Although described later in detail, the first photoelectric converter 110 and the second photoelectric converter 120 each include a photoelectric conversion layer that generates electric charge upon absorption of light.

The multilayer photoelectric converter 100 has, for example, the sensitivity characteristics illustrated in FIG. 2. In FIG. 2, the sensitivity characteristic of the first photoelectric converter 110 is represented by a dashed line, and the sensitivity characteristic of the second photoelectric converter 120 is represented by a solid line. The sensitivity characteristic of the first photoelectric converter 110, and the sensitivity characteristic of the second photoelectric converter 120 respectively correspond to, for example, the light absorption characteristic of the first photoelectric converter 110, and the light absorption characteristic of the second photoelectric converter 120. Accordingly, the light absorption spectrum of the photoelectric conversion layer of the first photoelectric converter 110, and the light absorption spectrum of the photoelectric conversion layer of the second photoelectric converter 120 can be respectively regarded as the sensitivity of the first photoelectric converter 110, and the sensitivity of the second photoelectric converter 120.

Light is incident on the multilayer photoelectric converter 100 from a side near the first photoelectric converter 110. Light that has passed through the first photoelectric converter 110 is incident on the second photoelectric converter 120. As illustrated in FIG. 2, the first photoelectric converter 110 has a sensitivity characteristic with a longest-wavelength peak in sensitivity (i.e., local maximum in sensitivity) present at a wavelength Ala. The sensitivity characteristic of the first photoelectric converter 110 has a cutoff in sensitivity at a wavelength λ1c longer than the wavelength λ1a. Therefore, for example, the photoelectric conversion layer within the first photoelectric converter 110 absorbs light at wavelengths shorter than the wavelength λ1c, and has a longest-wavelength local maximum in light absorption at the wavelength λ1a. The first photoelectric converter 110 has substantially no sensitivity to wavelengths longer than or equal to the wavelength λ1c. The second photoelectric converter 120 has a sensitivity characteristic with a longest-wavelength peak in sensitivity (i.e., local maximum in sensitivity) present at a wavelength λ2a. The sensitivity characteristic of the second photoelectric converter 120 exhibits a cutoff in sensitivity at a wavelength λ2c longer than the wavelength λ2a. Therefore, for example, the photoelectric conversion layer within the second photoelectric converter 120 absorbs light at wavelengths shorter than the wavelength λ2c, and has a longest-wavelength local maximum in light absorption at the wavelength λ2a. The second photoelectric converter 120 has substantially no sensitivity to wavelengths longer than or equal to the wavelength λ2c.

As illustrated in FIG. 2, in the sensitivity characteristics of the multilayer photoelectric converter 100, the wavelength λ1a is shorter than the wavelength λ2a. That is, the multilayer photoelectric converter 100 is configured to satisfy the following relationship: λ1a<λ2a. The sensitivity of the second photoelectric converter 120 at the wavelength λ2a is less than the sensitivity of the first photoelectric converter 110 at the wavelength λ1a.

As illustrated in FIGS. 3A and 3B, when a natural light source such as thermal radiation is used for measurement, its intensity as a function of wavelength is uncontrollable. When the temperature of a substance at 400 K having the radiation characteristics as illustrated in FIG. 3B is to be computed from the intensity ratio between a wavelength of light centered at 1.4 μm and a wavelength of light centered at 1.8 um, the two wavelengths of light differ significantly in intensity. More specifically, the light centered at 1.4 um, which is the shorter wavelength, has a lower intensity. As described above, the second photoelectric converter 120 is made to have, at the peak wavelength λ2a longer than the wavelength λ1a, a sensitivity less than the sensitivity of the first photoelectric converter 110 at the peak wavelength λ1a. This results in decreased sensitivity of the second photoelectric converter 120, which performs photoelectric conversion on high-intensity, longer-wavelength light. This makes it possible to, for example, increase the signal output of the first photoelectric converter 110, which performs photoelectric conversion on low-intensity, shorter-wavelength light, while reducing saturation of the signal output of the second photoelectric converter 120, which performs photoelectric conversion on high-intensity, longer-wavelength light. This allows for improved detection accuracy of different wavelengths of light, and consequently accurate temperature measurement.

The multilayer photoelectric converter 100 having the sensitivity characteristics mentioned above can be used not only for measurement of temperature but also for, for example, situations where, in performing some heat treatment in a sealed furnace, the proportion of a substance or the progress of alteration of the substance is to be spectroscopically evaluated. Even for such situations, the multilayer photoelectric converter 100 makes it possible to increase the possible measurement range in performing measurement by using thermal radiation itself as a light source. For example, there are many applications where, for example, the characteristics of a substance are measured by using different wavelengths of light, such as when a change in light absorption due to decomposition or alteration of the substance is measured based on a change relative to the absorption at a reference wavelength, or when the dissolution of powder is measured based on the wavelength dependence of light scattering. Using the multilayer photoelectric converter 100 according to Embodiment 1 facilitates using thermal radiation itself as a light source.

There are cases when, for example, the characteristics of a substance are measured by using light radiated through some material, such as when such measurement is performed by using light in the wavelength range from the visible to the short-wave infrared that is radiated through a resin that has been colored for decoration, or when such measurement is performed by using light in the wavelength range from the ultraviolet to the visible that is radiated through a glass. In such cases, the transmissivity of the material is determined by another factor, and thus not easily changeable. For example, in the case of the light radiated through the colored resin, the light transmissivity of the resin decreases in the visible wavelength range, and thus the light decreases in intensity in the visible range shorter in wavelength than the short-wave infrared range. In the case of the light radiated through the glass, the light transmissivity of the glass decreases in the ultraviolet wavelength range, and thus the light decreases in intensity in the ultraviolet range shorter in wavelength than the visible range. With the multilayer photoelectric converter 100 according to Embodiment 1, wavelengths of light at which the intensity decreases as described above can be detected with high sensitivity. This allows different wavelengths of light to be detected with improved accuracy. Therefore, the multilayer photoelectric converter 100 according to Embodiment 1 can be used even for cases where measurement needs to be performed by using light in a wavelength region where light transmissivity changes sharply with wavelength.

### Sensitivity Characteristics

The sensitivity characteristics of the multilayer photoelectric converter 100 according to Embodiment 1 are now described in more detail.

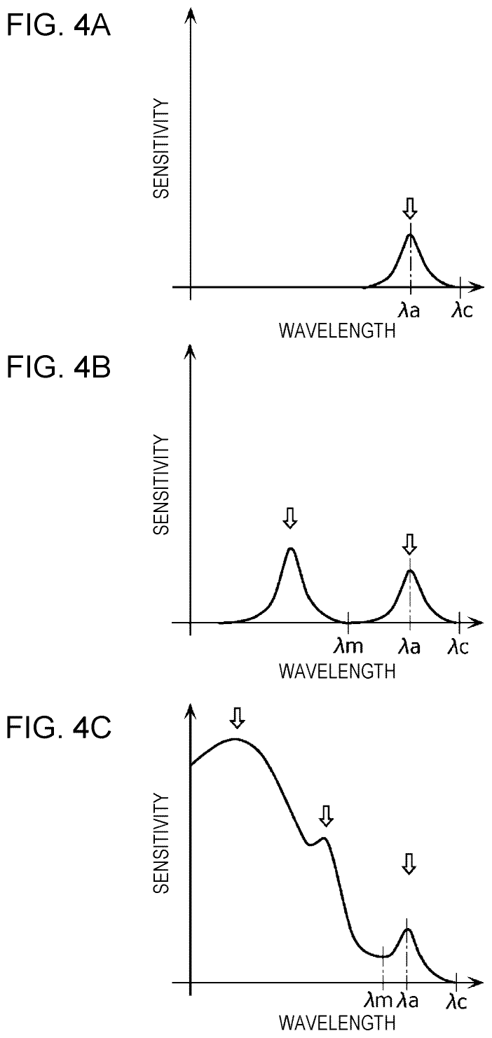

FIGS. 4A to 4C each schematically illustrate an example of the sensitivity characteristic of a single photoelectric converter. Reference is made first to FIGS. 4A to 4C to describe the sensitivity characteristic of the photoelectric converter, and the definitions of wavelengths that characterize the sensitivity characteristic.

FIG. 4A illustrates an exemplary sensitivity characteristic that has a local maximum in sensitivity only at a wavelength λa. The sensitivity characteristic illustrated in FIG. 4A has a local maximum in sensitivity at the wavelength λa, and at the same time, has a global maximum in sensitivity at the wavelength λa. In the sensitivity characteristic illustrated in FIG. 4A, the sensitivity decreases at wavelengths longer than the wavelength λa, and the wavelength at which the photoelectric converter substantially loses its sensitivity corresponds to a wavelength λc. The wavelength at which the photoelectric converter substantially loses its sensitivity means the longer one of the following wavelengths: the wavelength at which the sensitivity becomes less than or equal to one-twentieth of the sensitivity at the wavelength λa; and the wavelength at which the quantum efficiency of the photoelectric converter becomes less than or equal to 1%.

FIGS. 4B and 4C each illustrate an exemplary sensitivity characteristic with multiple local maxima in sensitivity. Herein, among the local maxima in sensitivity, the one at the longest wavelength is referred to as peak in sensitivity, and the wavelength at which the peak in sensitivity occurs is defined as the wavelength λa. The sensitivity characteristics illustrated in FIGS. 4B and 4C differ from the sensitivity characteristic illustrated in FIG. 4A in that, at wavelengths shorter than the wavelength λa, the sensitivity decreases relative to the sensitivity at the wavelength λa and exhibits a local minimum at a wavelength λm, and then increases again. The sensitivity characteristics illustrated in FIGS. 4B and 4C thus have multiple local maxima in sensitivity. In the sensitivity characteristic illustrated in FIG. 4B, the photoelectric converter substantially loses its sensitivity at the wavelength λm. In contrast, in the sensitivity characteristic illustrated in FIG. 4C, the photoelectric converter does not lose its sensitivity even at the wavelength λm but has a sensitivity even at the wavelength λm. In the example illustrated in FIG. 4B, a single local maximum in sensitivity exists at wavelengths shorter than the wavelength λm. Alternatively, however, multiple local maxima in sensitivity may exist at wavelengths shorter than the wavelength λm. In the example illustrated in FIG. 4C, multiple local maxima in sensitivity exist at wavelengths shorter than the wavelength λm. Alternatively, however, a single local maximum in sensitivity may exist at wavelengths shorter than the wavelength λm.

The first photoelectric converter 110 and the second photoelectric converter 120 according to Embodiment 1 each have, for example, one of the sensitivity characteristics illustrated in FIGS. 4A to 4C. Herein, to distinguish between wavelengths associated with different photoelectric converters, an index is added to each of the wavelengths λ described above with reference to FIGS. 4A to 4C. More specifically, an index of “1” is assigned to each wavelength associated with the sensitivity characteristic of the first photoelectric converter 110, and an index of “2” is assigned to each wavelength associated with the sensitivity characteristic of the second photoelectric converter 120. For example, the peak wavelength λa in sensitivity for the first photoelectric converter 110 is denoted as wavelength λ1a. Herein, an element such as “wavelength λ1a” within an inequality or other mathematical expressions is denoted simply as, for example, “λ1a.” For example, “λ1a” within an inequality is a numeric value (nm) representing a wavelength corresponding to the wavelength λ1a.

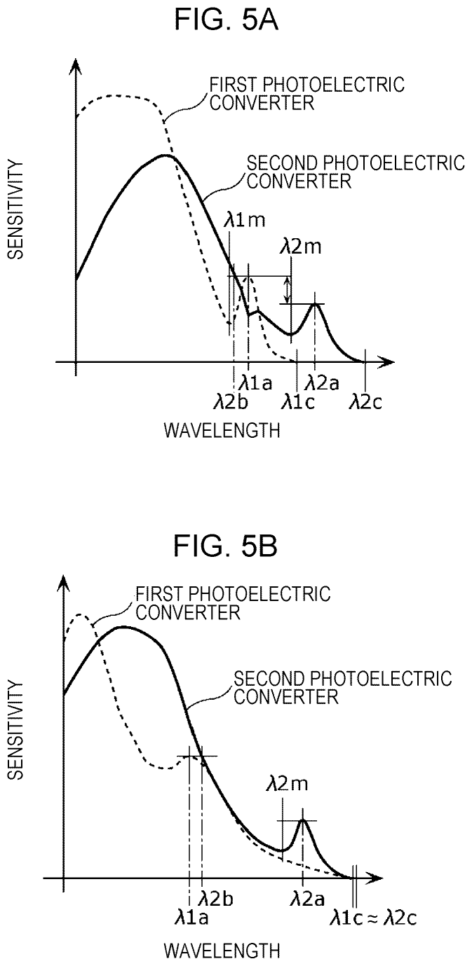

Reference is now made to FIG. 5A to describe in detail the sensitivity characteristics of the multilayer photoelectric converter 100 according to Embodiment 1. FIGS. 5A and 5B each illustrate the sensitivity characteristics of the multilayer photoelectric converter 100 according to Embodiment 1. FIG. 5A illustrates the sensitivity characteristics of the multilayer photoelectric converter 100 similar to the sensitivity characteristics illustrated in FIG. 2.

As illustrated in FIG. 5A, the first photoelectric converter 110 has a sensitivity characteristic in which, at wavelengths shorter than the wavelength λ1a, the sensitivity of the first photoelectric converter 110 decreases relative to the sensitivity at the wavelength λ1a and exhibits a local minimum at a wavelength λ1m. Further, in the sensitivity characteristic of the first photoelectric converter 110, the sensitivity of the first photoelectric converter 110 increases at wavelengths shorter than the wavelength λ1m. The first photoelectric converter 110 is thus capable of performing photoelectric conversion on light at wavelengths shorter than the wavelength λ1m. Therefore, in detecting light such as thermal radiation, the signal output of the first photoelectric converter 110, which performs photoelectric conversion on low-intensity, shorter-wavelength light, can be further increased.

The second photoelectric converter 120 has a sensitivity characteristic in which, at wavelengths shorter than the wavelength λ2a, the sensitivity of the second photoelectric converter 120 decreases relative to the sensitivity at the wavelength λ2a and exhibits a local minimum at a wavelength λ2m. Further, in the sensitivity characteristic of the second photoelectric converter 120, the sensitivity of the second photoelectric converter 120 increases at wavelengths shorter than the wavelength λ2m, and at a wavelength λ2b, becomes substantially equal to the sensitivity of the first photoelectric converter 110 at the wavelength λ1a. If, as described above, the second photoelectric converter 120 has a sensitivity characteristic as illustrated in FIG. 4B or 4C that has a wavelength at which the sensitivity of the second photoelectric converter 120 is higher than the sensitivity of the first photoelectric converter 110 at the wavelength λ1a, for example, the wavelength λ1a is longer than the wavelength λ2b, and the wavelength λ1c is shorter than the wavelength λ2c. That is, when the wavelengths illustrated in FIG. 5A are defined in addition to the wavelengths defined as described above with reference to FIG. 2, the following relationship is satisfied for the multilayer photoelectric converter 100: λ2b<λ1a, and λ1c<λ2c. That is, the sensitivity characteristic of the first photoelectric converter 110, and the sensitivity characteristic of the second photoelectric converter 120 have the relationship between wavelengths mentioned above. This allows for improved accuracy of separation between the following signals: a signal output based on light with wavelengths centered at the wavelength λ1a; and a signal output based on light with wavelengths centered at the wavelength λ2a.

More specifically, in the multilayer photoelectric converter 100, a signal output based on light with wavelengths centered at the wavelength λ1a corresponds to a signal output from the first photoelectric converter 110, and a signal output based on light with wavelengths centered at the wavelength λ2a corresponds to a signal output from the second photoelectric converter 120. Due to the above-mentioned sensitivity characteristic of the second photoelectric converter 120, at the wavelength λ1a, the sensitivity of the second photoelectric converter 120 is lower than the sensitivity of the first photoelectric converter 110. This helps to ensure that even when a portion of light with the wavelength λ1a is incident on the second photoelectric converter 120 without being absorbed by the first photoelectric converter 110, the signal output from the second photoelectric converter 120 is less susceptible to the influence of the light with the wavelength λ1a. This in turn allows for improved accuracy of separation between the signal output from the first photoelectric converter 110 and the signal output from the second photoelectric converter 120.

If the second photoelectric converter 120 has a sensitivity characteristic as illustrated in FIG. 4A or 4B that has no wavelength corresponding to the wavelength λ2b, this ensures that the sensitivity of the first photoelectric converter 110 at the wavelength λ1a does not fall below the sensitivity of the second photoelectric converter 120 at the wavelength λ1a. The accuracy of separation between signals thus improves.

As illustrated in FIG. 5B, if, due to the sensitivity characteristics of the multilayer photoelectric converter 100, the relationship λ1c≈λ2c is satisfied, the relationship λ2b<λ1a does not have to be satisfied. In this case as well, the sensitivity of the second photoelectric converter 120 at the wavelength λ2a is less than the sensitivity of the first photoelectric converter 110 at the wavelength λ1a. This allows the characteristics of a substance to be measured with improved accuracy as mentioned above.

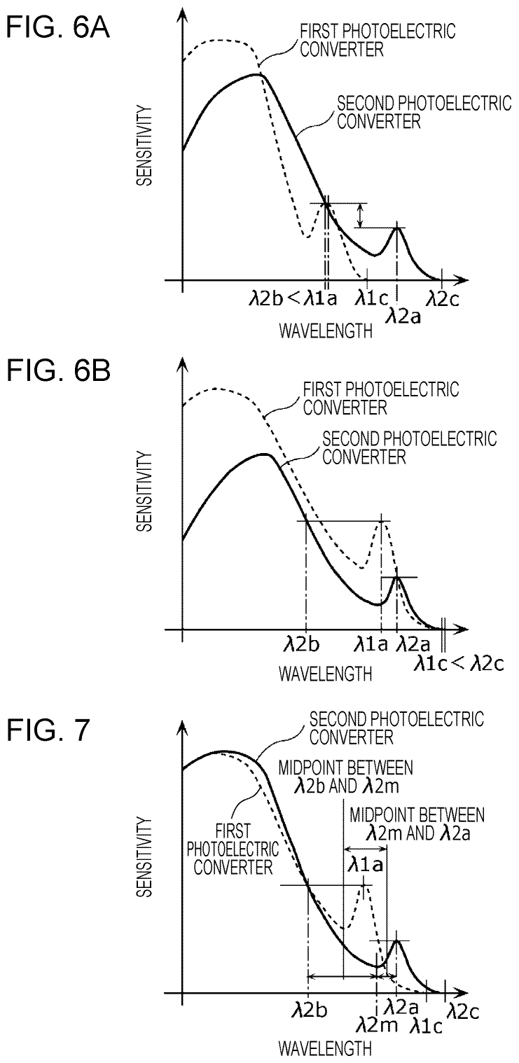

The relationship between wavelengths described above with reference to FIG. 5A is described below in detail with reference to FIGS. 6A and 6B. FIGS. 6A and 6B each illustrate the relationship between wavelengths in the sensitivity characteristics of the multilayer photoelectric converter 100.

For example, as the wavelength λ1a decreases from that in the sensitivity characteristics illustrated in FIG. 6A, the wavelength λ1a eventually becomes shorter than the wavelength λ2b. In such a case, the signal output from the first photoelectric converter 110 based on light with the wavelength λ1a becomes more likely to be buried in the signal output from the second photoelectric converter 120 based on light with the wavelength Ala. This means that when the sensitivity characteristics of the multilayer photoelectric converter 100 satisfy the relationship λ2b<λ1a, the second photoelectric converter 120 has a low sensitivity at the wavelength λ1a. As a result, the signal output from the first photoelectric converter 110 based on light with the wavelength λ1a becomes less likely to be buried in the signal output from the second photoelectric converter 120 based on light with the wavelength λ1a.

For example, as the wavelength λ1c increases from that in the sensitivity characteristics illustrated in FIG. 6B, the wavelength λ1c eventually becomes longer than the wavelength λ2c. In such a case, the signal output from the second photoelectric converter 120 based on light with the wavelength λ2a becomes more likely to be buried in the signal output from the first photoelectric converter 110 based on light with the wavelength λ2a. This means that when the sensitivity characteristics of the multilayer photoelectric converter 100 satisfy the relationship λ1c<λ2c, the first photoelectric converter 110 has a low sensitivity at the wavelength λ2a. As a result, the signal output from the second photoelectric converter 120 based on light with the wavelength λ2a becomes less likely to be buried in the signal output from the first photoelectric converter 110 based on light with the wavelength λ2a.

It is to be appreciated from the foregoing that, as illustrated in FIGS. 5A, 6A, and 6B, when the sensitivity characteristics of the multilayer photoelectric converter 100 satisfy the relationship: λ1c<λ2c, and λ2b<λ1a, in particular, the accuracy of separation between signals can be improved.

Reference is now made to FIG. 7 to describe another example of the sensitivity characteristics of the multilayer photoelectric converter 100. FIG. 7 schematically illustrates another example of the sensitivity characteristics of the multilayer photoelectric converter 100. As illustrated in FIG. 7, the presence of the wavelength λ1a in the vicinity of the wavelength λ2m allows for further improved accuracy of separation between the signal output from the first photoelectric converter 110 based on light with the wavelength λ1a, and the signal output from the second photoelectric converter 120 based on light with the wavelength λ2a. More specifically, as illustrated in FIG. 7, the wavelength λ1a is located within a range longer than the mean of the wavelength λ2b and the wavelength λ2m, and shorter than the mean of the λ2m and the wavelength λ2a. This allows for further improved accuracy of separation between signals. That is, from the viewpoint of improved accuracy of separation between signals, the multilayer photoelectric converter 100 may be configured to satisfy the following relationship:

(λ2b+λ2m)/2<λ1a<(λ2m+λ2a)/2.

### Detailed Configuration of Multilayer Photoelectric Converter

Components of the multilayer photoelectric converter 100 according to Embodiment 1 are described below in detail.

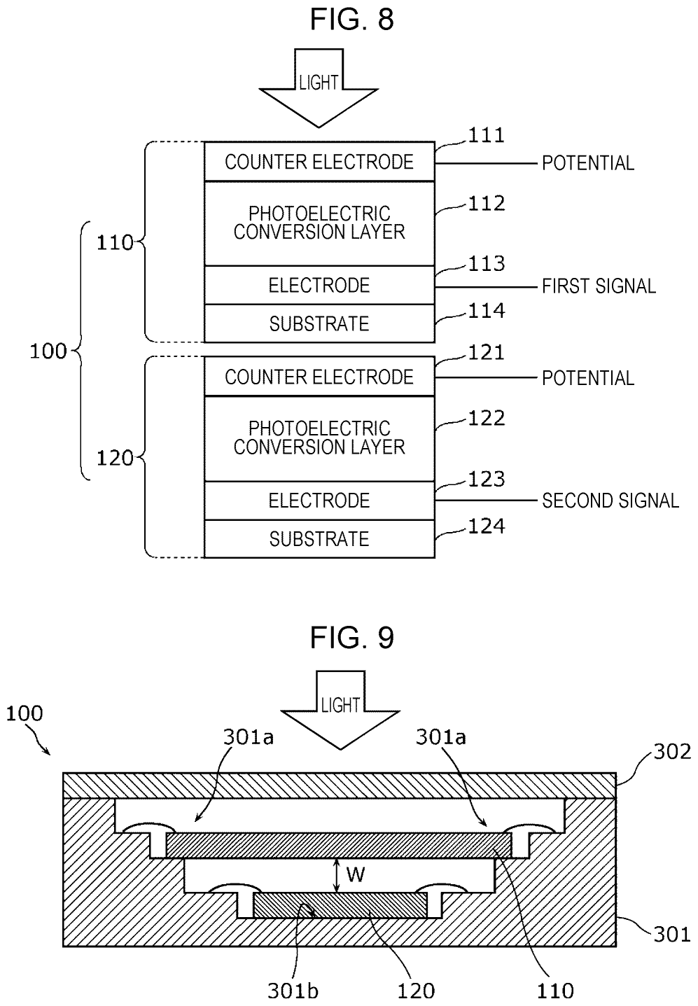

FIG. 8 schematically illustrates a detailed configuration of the multilayer photoelectric converter 100 according to Embodiment 1. The first photoelectric converter 110 and the second photoelectric converter 120 of the multilayer photoelectric converter 100 according to Embodiment 1 are, for example, photodiodes or photoconductors configured as illustrated in FIG. 8. The following description mainly focuses on an exemplary case where the first photoelectric converter 110 and the second photoelectric converter 120 are photodiodes. In this case, charge generated through photoelectric conversion in each of the first photoelectric converter 110 and the second photoelectric converter 120 is output as a signal from an electrode.

As illustrated in FIG. 8, the first photoelectric converter 110 includes an electrode 113, a counter electrode 111, a photoelectric conversion layer 112, and a substrate 114. The counter electrode 111 is located opposite to the electrode 113. The photoelectric conversion layer 112 is located between the electrode 113 and the counter electrode 111. The second photoelectric converter 120 includes an electrode 123, a counter electrode 121, a photoelectric conversion layer 122, and a substrate 124. The counter electrode 121 is located opposite to the electrode 123. The photoelectric conversion layer 122 is located between the electrode 123 and the counter electrode 121. Herein, each of the electrode 113 and the electrode 123 corresponds to an example of a first electrode. Each of the counter electrode 111 and the counter electrode 121 corresponds to an example of a second electrode. At least one of the substrate 114 or the substrate 124 does not have to be provided if the first photoelectric converter 110 and the second photoelectric converter 120 are to be provided on another substrate or base.

The photoelectric conversion layer 112 and the photoelectric conversion layer 122 each generate, upon incidence of light thereon, pairs of holes and electrons, which are excitons. That is, the photoelectric conversion layer 112 and the photoelectric conversion layer 122 each generate electric charge through photoelectric conversion. The photoelectric conversion layer 112 and the photoelectric conversion layer 122 each include a photoelectric conversion material that absorbs incident light, and generates pairs of holes and electrons. The photoelectric conversion material is, for example, a semiconducting inorganic material or a semiconducting organic material. The photoelectric conversion layer 112 and the photoelectric conversion layer 122 may each include an acceptor material that accepts the charge generated by the photoelectric conversion material.

At least one of the photoelectric conversion layer 112 or the photoelectric conversion layer 122 includes, for example, a quantum dot. A quantum dot is a material that exhibits a three-dimensional quantum confinement effect. A quantum dot is a nanocrystal with a diameter smaller than the exciton Bohr radius of the material constituting the quantum dot. Many such quantum dots range in diameter from about 2 nm to 10 nm. The inclusion of a quantum dot in each of the photoelectric conversion layer 112 and the photoelectric conversion layer 122 makes it easily possible to provide a photoelectric converter with a peak wavelength in sensitivity within a range of wavelengths from the near-infrared to the mid-infrared. If the photoelectric conversion layer 112 and the photoelectric conversion layer 122 each include a quantum dot, the first photoelectric converter 110 and the second photoelectric converter 120 each have the sensitivity characteristic as illustrated in FIG. 4C.

The quantum dot includes at least one of a metal pnictide, a metal chalcogenide, a metal halide, or a metal chalcohalide. In particular, the quantum dot may include, among these elements, a metal chalcogenide. According to Embodiment 1, the metal chalcogenide is, for example, PbS, PbSe, PbTe, CdS, CdSe, CdTe, or HgCdTe. This allows the sensitivity peak wavelength of the photoelectric converter to be controlled over a wide range of wavelengths from the visible to the infrared.

The surface of quantum dots is, for example, modified with a ligand. Available quantum dots often have a surface modified with a long-chain alkyl ligand for improved dispersibility during synthesis. Since a long-chain alkyl ligand hinders charge transfer, for example, such a long-chain alkyl ligand used to modify the surface of quantum dots is substituted by a short molecular ligand, a semiconducting ligand with π-bonding, or an atomic ligand such as a halide ion. Existing known methods that can be used for the substitution include a solid-phase substitution method and a liquid-phase substitution method. In the solid-phase substitution method, quantum dots are formed into a film (solid phase) and then exposed to a solution of the substituting ligand to allow substitution to occur due to the concentration and binding energy differences between the ligands. In the liquid-phase substitution method, ligand substitution takes place in solution (liquid phase). The solid-phase substitution method is not constrained by the dispersibility in solution after the substitution, and thus can be used for a wide variety of applications. With the solid-phase substitution method, the thickness of the film that can undergo substitution is limited by the ligand diffusion length in the thin film. Thus, thin film formation and solid-phase substitution are repeated until a desired film thickness is obtained. With liquid-phase substitution, thin-film formation is possible after ligand substitution. Liquid-phase substitution needs to be performed under a condition that ensures stable dispersion in solution after substitution. This may limit the applicable combinations of quantum dots, ligands, and solvents in some cases.

The band gap of a quantum dot can be controlled by adjusting the particle size of the quantum dot. For example, the greater the particle size of a quantum dot, the narrower the band gap of the quantum dot. Accordingly, the greater the particle size of a quantum dot, the greater the light absorption peak wavelength of the quantum dot. That is, the sensitivity peak wavelength of the photoelectric converter can be adjusted by adjusting the particle size of the quantum dot.

The light absorption peak wavelength of the quantum dot can be adjusted by adjusting the constituent elements of the quantum dot material. For example, compared to PbS, PbSe characteristically allows for a lower band gap energy in bulk crystals, and consequently a longer absorption peak wavelength when used in the quantum dot.

One exemplary way to form the photoelectric conversion layer 112 is to deposit by spin-coating, onto one of the electrode 113 or the counter electrode 111, a dispersion containing a photoelectric conversion material such as the quantum dot adjusted as described above. The photoelectric conversion layer 112 may be formed by other methods such as vapor deposition. In this case, the other one of the electrode 113 or the counter electrode 111 is then deposited onto the photoelectric conversion layer 112, and thus the first photoelectric converter 110 is obtained. The second photoelectric converter 120 can be also produced by a method similar to the method for producing the first photoelectric converter 110.

Each of the electrode 113, the electrode 123, the counter electrode 111, and the counter electrode 121 is, for example, a film-like electrode. Charge generated in the photoelectric conversion layer 112 is output from the electrode 113 as a first signal, which is a signal output from the first photoelectric converter 110. The first signal is thus read out from the electrode 113. Charge generated in the photoelectric conversion layer 122 is output from the electrode 123 as a second signal, which is a signal output from the second photoelectric converter 120. The second signal is thus read out from the electrode 123. The counter electrode 111 and the counter electrode 121 respectively receive, for example, via wiring (not illustrated), a voltage for setting the counter electrode 111 to a predetermined potential, and a voltage for setting the counter electrode 121 to a predetermined potential. A bias voltage is thus applied between the electrode 113 and the counter electrode 111, and between the electrode 123 and the counter electrode 121. For example, the predetermined potentials are set in such a way the potential of the counter electrode 111 and the potential of the counter electrode 121 are higher than the potential of the electrode 113 and the potential of the electrode 123, respectively. That is, the predetermined potentials are set in such a way that, of the pairs of electrons and holes generated in the photoelectric conversion layer 112 and the photoelectric conversion layer 122, the electrons move to the counter electrode 111 and the counter electrode 121, and the holes move to the electrode 113 and the electrode 123. As a result, the holes are collected as signal charge by the electrode 113 and the electrode 123. The voltage supplied to the counter electrode 111, and the voltage supplied to the counter electrode 121 may have the same magnitude, or may have different magnitudes. The predetermined potentials may be set in such a way that, of the pairs of electrons and holes generated in the photoelectric conversion layer 112 and the photoelectric conversion layer 122, the holes move to the counter electrode 111 and the counter electrode 121, and the electrons move to the electrode 113 and the electrode 123.

The electrode 113, the electrode 123, the counter electrode 111, and the counter electrode 121 transmit at least light within a specific wavelength range. The specific wavelength range is, for example, a wavelength range including the wavelength λ1a and the wavelength λ2a. As used herein, the expression “transmit light at a given wavelength” or “transmissive of light at a given wavelength” may, for example, mean having a transmittance of greater than or equal to 50% for light at the given wavelength, or mean having a transmittance of greater than or equal to 70% for light at the given wavelength.

In one example, the electrode 113, the electrode 123, the counter electrode 111, and the counter electrode 121 are made of a material that transmits a range of wavelengths from the visible to the infrared. Suitable examples of the material that transmits a range of wavelengths from the visible to the infrared include transparent conducting oxides (TCOs) such as an indium tin oxide (ITO) and an aluminum zinc oxide (AZO), silver nanowires, graphene, and metal-carbon nanotubes. In another example, the electrode 113, the electrode 123, the counter electrode 111, and the counter electrode 121 may be made of a material that transmits only infrared radiation. Suitable examples of the material that transmits only infrared radiation include a semiconductor material with a band gap larger than a desired wavelength, such as doped silicon.

In the example illustrated in FIG. 8, the counter electrode 111 is located at the incident side of the photoelectric conversion layer 112, and the electrode 113 is located at a side of the photoelectric conversion layer 112 opposite from the incident side. The counter electrode 121 is located at the incident side of the photoelectric conversion layer 122, and the electrode 123 is located at a side of the photoelectric conversion layer 122 opposite from the incident side. The positioning of the electrode 113, the electrode 123, the counter electrode 111, and the counter electrode 121 is not particularly limited as long as the electrode 113 and the counter electrode 111 are positioned to sandwich the photoelectric conversion layer 112, and the electrode 123 and the counter electrode 121 are positioned to sandwich the photoelectric conversion layer 122. For example, the position of the counter electrode 111, and the position of the electrode 113 may be interchangeable. Likewise, the position of the counter electrode 121, and the position of the electrode 123 may be interchangeable.

The substrate 114 is a support substrate that supports the electrode 113, the counter electrode 111, and the photoelectric conversion layer 112. The substrate 124 is a support substrate that supports the electrode 123, the counter electrode 121, and the photoelectric conversion layer 122. In the example illustrated in FIG. 8, the substrate 114 is located at a side of the electrode 113 opposite from the incident side of the electrode 113. The substrate 124 is located at a side of the electrode 123 opposite from the incident side of the electrode 123. The substrate 114 may be located at the incident side of the counter electrode 111. Likewise, the substrate 124 may be located at the incident side of the counter electrode 121. That is, the substrate 114 may simply be located opposite to the photoelectric conversion layer 112 across the counter electrode 111 or the electrode 113. The substrate 124 may simply be located opposite to the photoelectric conversion layer 122 across the counter electrode 121 or the electrode 123.

The substrate 114 and the substrate 124 transmit, for example, at least light within the above-mentioned wavelength range. Specific examples of the material of the substrate 114 and the substrate 124 include glasses that transmit at least part of the wavelength range from the near-infrared to the mid-infrared (e.g., BK7 from Kosci Sangyo Co., Ltd., and K-GIR79 from Sumita Optical Glass, Inc.), oxides such as silica glasses, semiconductors such as silicon or germanium, chalcogenide glasses, calcium fluoride, and magnesium fluoride. Other suitable examples of the material of the substrate 114 and the substrate 124 may include resin materials such as acrylic resin. It is to be noted, however, that some resin materials have relatively large absorption within the above-mentioned specific wavelength range. Thus, as required, the wavelength dependence of transmittance is corrected, and then the detection results obtained with the multilayer photoelectric converter 100 are used to measure, for example, the characteristics of a substance.

Among the electrode 113, the electrode 123, the counter electrode 111, the counter electrode 121, the substrate 114, and the substrate 124, those positioned opposite from the incident side of the photoelectric conversion layer 112 may be non-transmissive of light with the wavelength λ1a, and may be, for example, transmissive of light in a wavelength range that includes the wavelength λ2a but does not include the wavelength Ala. Among the counter electrode 121, the electrode 123, and the substrate 124, those positioned opposite from the incident side of the photoelectric conversion layer 122 may be non-transmissive of light in the above-mentioned specific wavelength range, and may be made of, for example, a material having light-blocking property such as a material including a conductive metallic compound or metal.

The first photoelectric converter 110 and the second photoelectric converter 120 may be photoconductors as described above. In this case, charge is injected from each of the counter electrode 111 and the counter electrode 121 in accordance with the amount of charge generated through photoelectric conversion, and mainly the injected charge is output as a signal from each of the electrode 113 and the electrode 123.

### Multilayer Structure of Multilayer Photoelectric Converter

Reference is now made to a specific structure including a stack of the first photoelectric converter 110 and the second photoelectric converter 120 that have been independently formed by deposition. The first photoelectric converter 110 and the second photoelectric converter 120 that have been independently formed by deposition are, for example, stacked in spaced relation to each other. FIG. 9 is a schematic cross-sectional view of an example of the multilayer structure of the multilayer photoelectric converter 100 according to Embodiment 1.

As illustrated in FIG. 9, the multilayer photoelectric converter 100 includes, for example, a package 301 with a pair of stepped structures 301a. The first photoelectric converter 110 and the second photoelectric converter 120 are mounted to the package 301. The package 301 is an example of a retainer.

The package 301 accommodates the first photoelectric converter 110, and the second photoelectric converter 120. The package 301 includes the pair of stepped structures 301a positioned to sandwich the first photoelectric converter 110 and the second photoelectric converter 120, and a recessed face 301b located between the pair of stepped structures 301a and to which the second photoelectric converter 120 is to be secured. Each of the pair of stepped structures 301a includes a step to which the wiring for the second photoelectric converter 120 is to be connected, a step to which the first photoelectric converter 110 is to be secured, and a step to which the wiring for the first photoelectric converter 110 is to be connected. In the example illustrated in FIG. 9, each of the pair of stepped structures 301a further includes a step to which a protective substrate 302 for providing overall sealing is to be secured. The protective substrate 302 transmits light in the above-mentioned specific wavelength range.

The height differences between the steps in the pair of stepped structures 301a are such that the first photoelectric converter 110, the second photoelectric converter 120, and the protective substrate 302 are in spaced, non-contacting relation to each other. To ensure that non-uniformity resulting from optical interference does not occur due to the gap between the first photoelectric converter 110 and the second photoelectric converter 120, the corresponding steps in the pair of stepped structures 301a are at the same height. This allows the package 301 to retain a constant gap W between the first photoelectric converter 110 and the second photoelectric converter 120. That is, the first photoelectric converter 110 and the second photoelectric converter 120 are secured in place within the package 301 in parallel and spaced relation to each other. In the example illustrated in FIG. 9, the second photoelectric converter 120 has a width greater than the width of the first photoelectric converter 110.

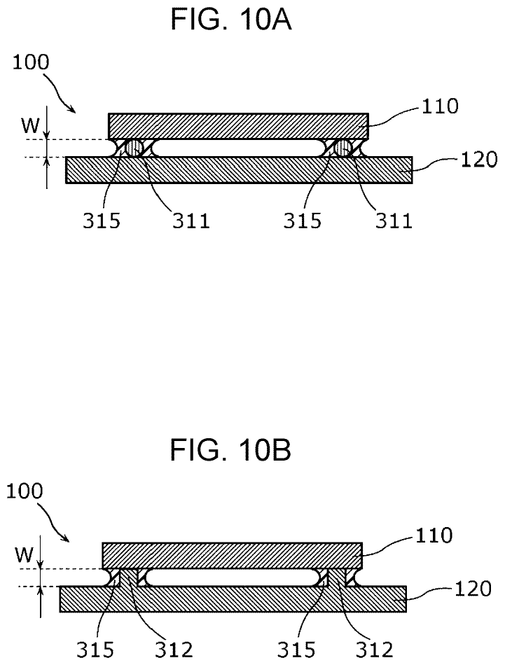

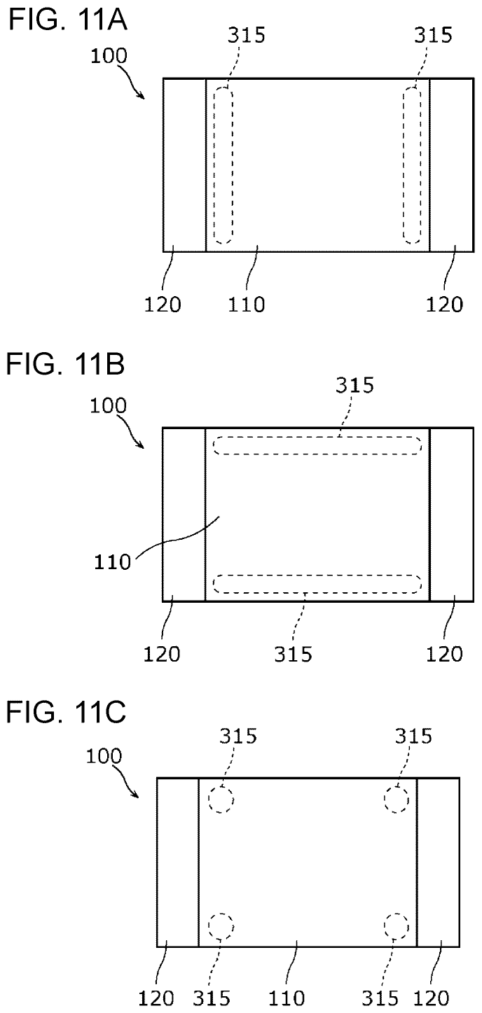

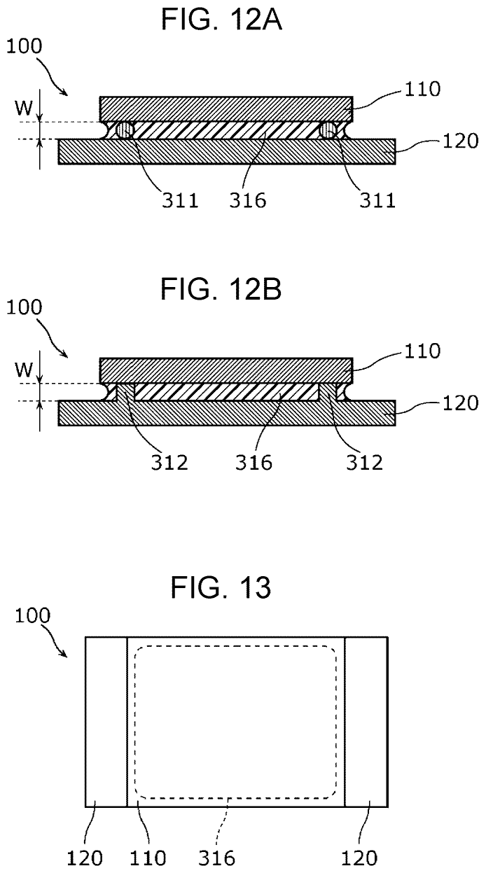

The structure of the stack of the first photoelectric converter 110 and the second photoelectric converter 120 is not limited to the example illustrated in FIG. 9. For example, the first photoelectric converter 110 and the second photoelectric converter 120 may be bonded to each other with an adhesive. FIGS. 10A and 10B are each a schematic cross-sectional view of another example of the multilayer structure of the multilayer photoelectric converter 100 according to Embodiment 1. FIGS. 11A to 11C are each a schematic plan view of an example of the shape of the multilayer structure illustrated in FIG. 10A or 10B. FIGS. 12A and 12B are each a schematic cross-sectional view of still another example of the multilayer structure of the multilayer photoelectric converter 100 according to Embodiment 1. FIG. 13 is a schematic plan view of an example of the shape of the multilayer structure illustrated in FIG. 12A or 12B.

As illustrated in FIGS. 10A and 10B, the multilayer photoelectric converter 100 includes, for example, gap materials 311 or protrusions 312, and an adhesive 315. The gap materials 311 and the protrusions 312 each correspond to an example of a retainer.

The gap materials 311 are disposed on the second photoelectric converter 120 to retain the constant gap W between the first photoelectric converter 110 and the second photoelectric converter 120. The gap materials 311 are located between the first photoelectric converter 110 and the second photoelectric converter 120, and in contact with the first photoelectric converter 110 and the second photoelectric converter 120. In plan view, each gap material 311 is disposed in an end portion of the region where the first photoelectric converter 110 and the second photoelectric converter 120 overlap. Examples of the gap materials 311 include glass beads with a uniform particle size.

The protrusions 312 are provided on the upper face of the second photoelectric converter 120 to retain the constant gap W between the first photoelectric converter 110 and the second photoelectric converter 120. The upper face of each protrusion 312 is in contact with the first photoelectric converter 110. In plan view, each protrusion 312 is disposed in an end portion of the region where the first photoelectric converter 110 and the second photoelectric converter 120 overlap. The protrusions 312 are, for example, protrusions with a uniform height formed by a process such as a semiconductor process. The protrusions 312 may be provided on the lower face of the first photoelectric converter 110.

The adhesive 315 adheres to the first photoelectric converter 110 and the second photoelectric converter 120 at a location around each gap material 311 or each protrusion 312 to thereby secure the first photoelectric converter 110 and the second photoelectric converter 120 in place. In one example, as illustrated in FIGS. 11A and 11B, in plan view, the adhesive 315 is disposed in an end portion of the region where the first photoelectric converter 110 and the second photoelectric converter 120 overlap, in such a way that the adhesive 315 is positioned along each of two opposite peripheral edges of the region. In another example, as illustrated in FIG. 11C, in plan view, the adhesive 315 may be positioned at each of the four corners of the region where the first photoelectric converter 110 and the second photoelectric converter 120 overlap. Due to the above-mentioned examples of positioning, most of the region where the first photoelectric converter 110 and the second photoelectric converter 120 overlap is not covered with the adhesive 315. This allows light to be incident on the first photoelectric converter 110 and the second photoelectric converter 120, irrespective of the light-transmission characteristics of the adhesive 315. Suitable examples of the adhesive 315 may include adhesives commonly used to secure substrates in place, such as epoxy adhesives and acrylic adhesives.

As illustrated in FIGS. 11A to 11C, in one example, in plan view, the second photoelectric converter 120 is larger than the first photoelectric converter 110. This allows, for example, electrical wiring to be performed by use of a bonding pad or other features exposed at a location on the second photoelectric converter 120 that is not covered by the first photoelectric converter 110. In another example, in plan view, the first photoelectric converter 110 may be larger than the second photoelectric converter 120. The electrical wiring mentioned above can be performed in this case as well. In another example, in plan view, the first photoelectric converter 110 and the second photoelectric converter 120 may have the same size and completely overlap each other.

As illustrated in FIGS. 12A and 12B, the multilayer photoelectric converter 100 may include an adhesive 316, instead of the adhesive 315 illustrated in FIGS. 10A and 10B. The adhesive 316 fills the gap between the first photoelectric converter 110 and the second photoelectric converter 120, in a region inside the location where the gap materials 311 or the protrusions 312 are present. As a result, in substantially the entire region where the first photoelectric converter 110 and the second photoelectric converter 120 overlap, the first photoelectric converter 110 and the second photoelectric converter 120 are bonded to each other with the adhesive 316. In adhering the first photoelectric converter 110 and the second photoelectric converter 120 to each other, the adhesive 316 fills in the space between the first photoelectric converter 110 and the second photoelectric converter 120 to ensure that the gap W is not an air gap. This makes it possible to reduce the influence of reflection caused by the difference in refractive index between the second photoelectric converter 120 and such an air gap. In this case, the adhesive 316 is required to be a material that transmits light at a wavelength that is received by the second photoelectric converter 120. The adhesive 316 is, for example, transmissive of light at the wavelength λ2a. Examples of the adhesive 316 include epoxy adhesives, acrylate adhesives, and other adhesives used for optical path coupling in applications such as infrared optical communication. Specific examples of the adhesive include, but are not limited to, EPO-TEK 353ND from Rikei Corporation, as well as NTT-AT GA700 and AT6001 from NTT Advanced Technology Corporation.

The first photoelectric converter 110 and the second photoelectric converter 120 may be stacked directly on each other with no spacing therebetween. In this case, one of the substrate 114 or the substrate 124 does not have to be provided. The electrical connection to at least one of the first photoelectric converter 110 or the second photoelectric converter 120 may be made by a contact that penetrates one of the first photoelectric converter 110 or the second photoelectric converter 120, and that is connected to the other one of the first photoelectric converter 110 or the second photoelectric converter 120.

### Modification 1

A multilayer photoelectric converter according to Modification 1 of Embodiment 1 is now described. The following description of Modification 1 is directed to an exemplary multilayer photoelectric converter in which an electrode is shared between the first photoelectric converter 110 and the second photoelectric converter 120. The following description of Modification 1 focuses mainly on differences from Embodiment 1, and description of features similar to those in Embodiment 1 is omitted or simplified. The same applies to the description given below of Modification 2 and the subsequent modifications. That is, the following description of individual modifications focuses mainly on differences between Embodiment 1 and the modifications, and description of features similar to those in Embodiment 1 is omitted or simplified.

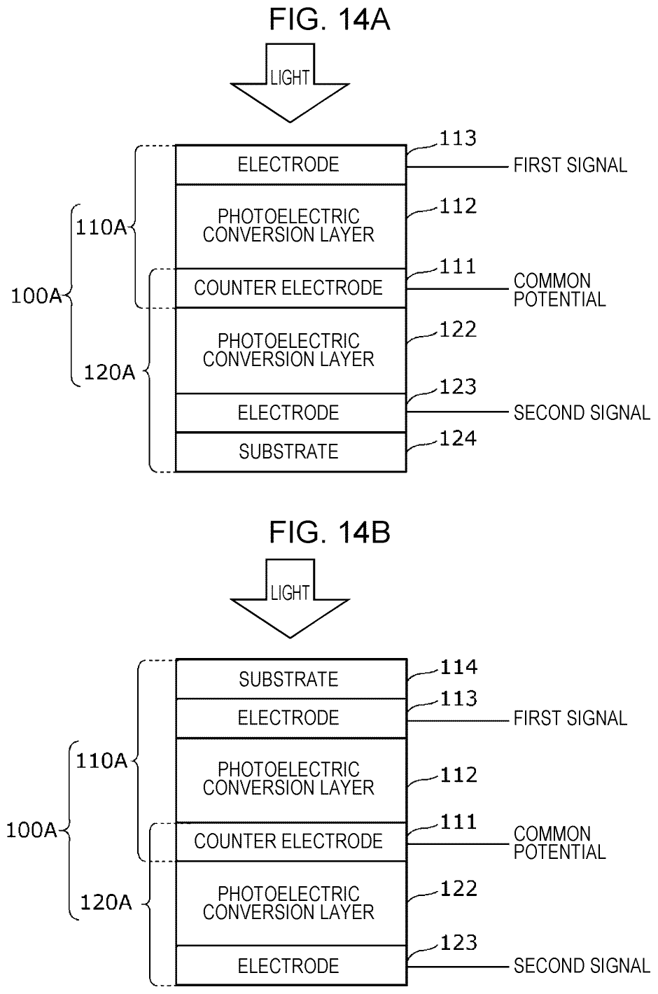

FIGS. 14A and 14B each schematically illustrate a configuration of a multilayer photoelectric converter 100A according to Modification 1. As illustrated in FIG. 14A, the multilayer photoelectric converter 100A includes a first photoelectric converter 110A, and a second photoelectric converter 120A. The first photoelectric converter 110A differs from the first photoelectric converter 110 mentioned above in that no substrate 114 is provided. More specifically, the first photoelectric converter 110A includes the counter electrode 111, the photoelectric conversion layer 112, and the electrode 113. The second photoelectric converter 120A differs from the second photoelectric converter 120 mentioned above in that the counter electrode 111 is provided instead of the counter electrode 121 of the second photoelectric converter 120. More specifically, the second photoelectric converter 120A includes the counter electrode 111, the photoelectric conversion layer 122, the electrode 123, and the substrate 124. As illustrated in FIG. 14A, the first photoelectric converter 110A and the second photoelectric converter 120A share the counter electrode 111. The multilayer photoelectric converter 100A includes, for example, the following components stacked on the substrate 124 in the order stated below: the electrode 123, the photoelectric conversion layer 122, the counter electrode 111, the photoelectric conversion layer 112, and the electrode 113. As illustrated in FIG. 14B, in another possible configuration of the multilayer photoelectric converter 100A, the first photoelectric converter 110A includes the substrate 114, and the second photoelectric converter 120A does not include the substrate 124. In the case of this configuration, the multilayer photoelectric converter 100A includes, for example, the following components stacked on the substrate 114 in the order stated below: the electrode 113, the photoelectric conversion layer 112, the counter electrode 111, the photoelectric conversion layer 122, and the electrode 123.

The counter electrode 111 is in contact with both of the two photoelectric conversion layers 112 and 122. In the multilayer photoelectric converter 100A, the first photoelectric converter 110A and the second photoelectric converter 120A share the counter electrode 111, and thus the counter electrode 111 is set at a common potential between the first photoelectric converter 110A and the second photoelectric converter 120A. At this time, the electrode 113 from which the first signal is to be read out, and the electrode 123 from which the second signal is to be read out are independent of each other, and thus the first signal and the second signal can be read out individually. As described above, separate electrodes are used to read out different signals. This makes it possible to prevent signal crosstalk, and consequently avoid noise.

### Modification 2

A multilayer photoelectric converter according to Modification 2 of Embodiment 1 is now described. The following description of Modification 2 is directed to an example in which a multilayer photoelectric converter includes long-pass filters.

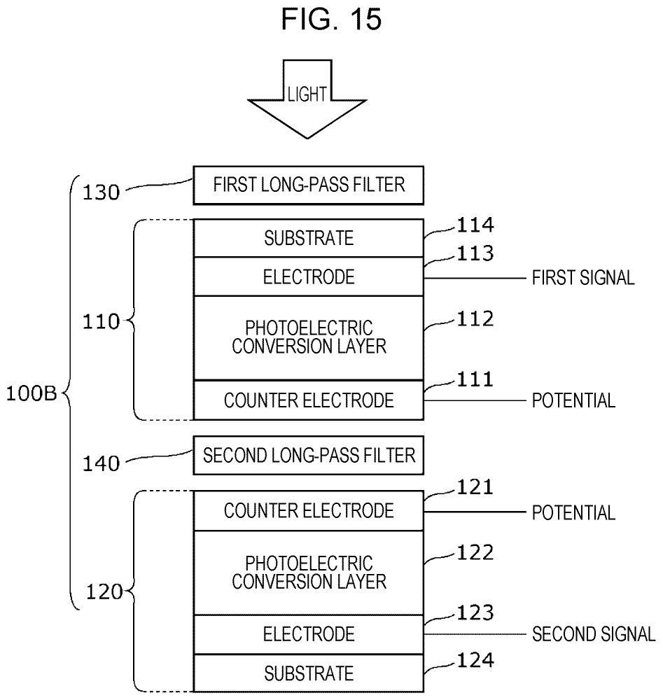

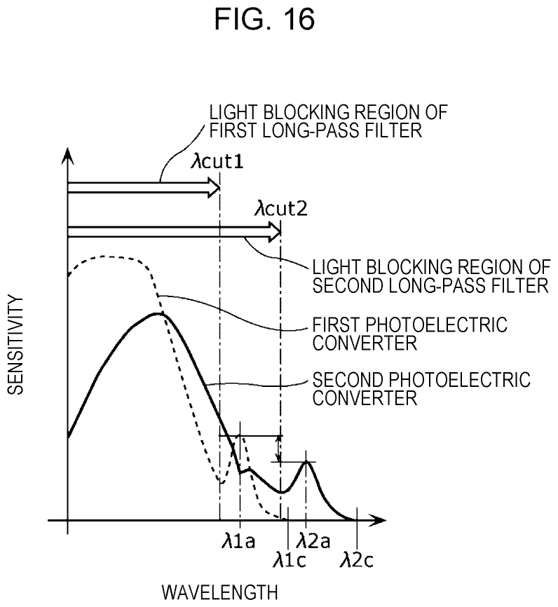

FIG. 15 schematically illustrates a configuration of a multilayer photoelectric converter 100B according to Modification 2. FIG. 16 illustrates the relationship between the sensitivity characteristics of the multilayer photoelectric converter 100B and the cutoff wavelengths of the long-pass filters.

As illustrated in FIG. 15, the multilayer photoelectric converter 100B differs from the multilayer photoelectric converter 100 according to Embodiment 1 in that the multilayer photoelectric converter 100B further includes a first long-pass filter 130 and a second long-pass filter 140, in addition to the first photoelectric converter 110 and the second photoelectric converter 120.

The first long-pass filter 130 is located at the incident side of the first photoelectric converter 110. That is, light transmitted through the first long-pass filter 130 is incident on the first photoelectric converter 110. As illustrated in FIG. 16, the first long-pass filter 130 has a light-blocking region in a range of wavelengths shorter than or equal to a cutoff wavelength λcut1. That is, the first long-pass filter 130 blocks light at wavelengths shorter than or equal to the cutoff wavelength λcut1, and transmits light at wavelengths longer than the cutoff wavelength λcut1. The cutoff wavelength λcut1 is shorter than the wavelength λ1a. As used herein, the term “light-blocking region” does not necessarily refer to a wavelength range where light is completely blocked. Rather, the term refers to, for example, a wavelength range where the transmittance is less than or equal to 10%. The light-blocking region may refer to a wavelength range where the transmittance is less than or equal to 1%.

In the case of, for example, thermal radiation, light at wavelengths shorter than the wavelength λ1a has sufficiently low intensity relative to the intensities at the wavelengths λ1a and λ2a. Thus, hardly any of the light is incident on the first photoelectric converter 110 and the second photoelectric converter 120, and is unlikely to introduce noise in the measurement of, for example, the characteristics of a substance. If, however, the environment in which imaging is performed includes a light source other than thermal radiation, such as lighting or an LED indicative of operational condition, a signal resulting from a sensitivity at a wavelength shorter than the wavelength λ1a may become a source of noise. Even in such a case, the first long-pass filter 130 provided at the incident side of the first photoelectric converter 110 blocks, among the wavelengths of light that are incident on the multilayer photoelectric converter 100, wavelengths of light shorter than or equal to the cutoff wavelength λcut1. This allows for noise reduction. The cutoff wavelength λcut 1 may be any wavelength shorter than the wavelength λ1a to ensure reduced interference with the detection of light by the multilayer photoelectric converter 100. From the viewpoint of effective noise reduction, the cutoff wavelength λcut1 is, for example, a wavelength longer than the wavelength of light that is a source of noise.

As illustrated in FIG. 15, the second long-pass filter 140 is located between the first photoelectric converter 110 and the second photoelectric converter 120. That is, light transmitted through the second long-pass filter 140 is incident on the second photoelectric converter 120. As illustrated in FIG. 16, the second long-pass filter 140 has a light-blocking region in a range of wavelengths shorter than or equal to a cutoff wavelength λcut2. That is, the second long-pass filter 140 blocks light at wavelengths shorter than or equal to the cutoff wavelength λcut2, and transmits light at wavelengths longer than the cutoff wavelength λcut2. The cutoff wavelength λcut2 is longer than the wavelength λ1a, and shorter than the wavelength λ2a. As described above, the second long-pass filter 140 with the cutoff wavelength λcut2 between the wavelength λ1a and the wavelength λ2a is disposed between the first photoelectric converter 110 and the second photoelectric converter 120. This allows transmission of light at wavelengths longer than or equal to the wavelength λ2a while blocking light at wavelengths shorter than or equal to the wavelength λ1a. This in turn leads to improved accuracy of separation between the first signal output from the first photoelectric converter 110 and the second signal output from the second photoelectric converter 120.

As the first long-pass filter 130 and the second long-pass filter 140, long-pass filters with the above-mentioned light-blocking regions are used. As such long-pass filters, colored glasses or dielectric multilayer films are used.

The multilayer photoelectric converter 100B may include one of the first long-pass filter 130 or the second long-pass filter 140.

Any one of an electrode, a counter electrode, or a substrate included in each of the first photoelectric converter 110 and the second photoelectric converter 120 may serve as the first long-pass filter 130 or the second long-pass filter 140. This allows for simplified structure. For example, in the first photoelectric converter 110, an electrode, a counter electrode, or a substrate that is located closer to the incident side of the first photoelectric converter 110 than is the photoelectric conversion layer 112 may serve as the first long-pass filter. For example, in the second photoelectric converter 120, an electrode, a counter electrode, or a substrate that is located closer to the incident side of the second photoelectric converter 120 than is the photoelectric conversion layer 122 may serve as the second long-pass filter. If the first photoelectric converter 110A and the second photoelectric converter 120A share the counter electrode 111 as in the case of Modification 1 of Embodiment 1, the counter electrode 111 is made to serve as the second long-pass filter 140 to allow for further simplified structure. For example, a properly doped, electrically conductive polysilicon electrode may be used to provide an electrode with a cutoff wavelength in the vicinity of 1100 nm.

### Modification 3

A multilayer photoelectric converter according to Modification 3 of Embodiment 1 is now described. The following description of Modification 3 is directed to an example in which the first photoelectric converter and the second photoelectric converter further include block layers and buffer layers.

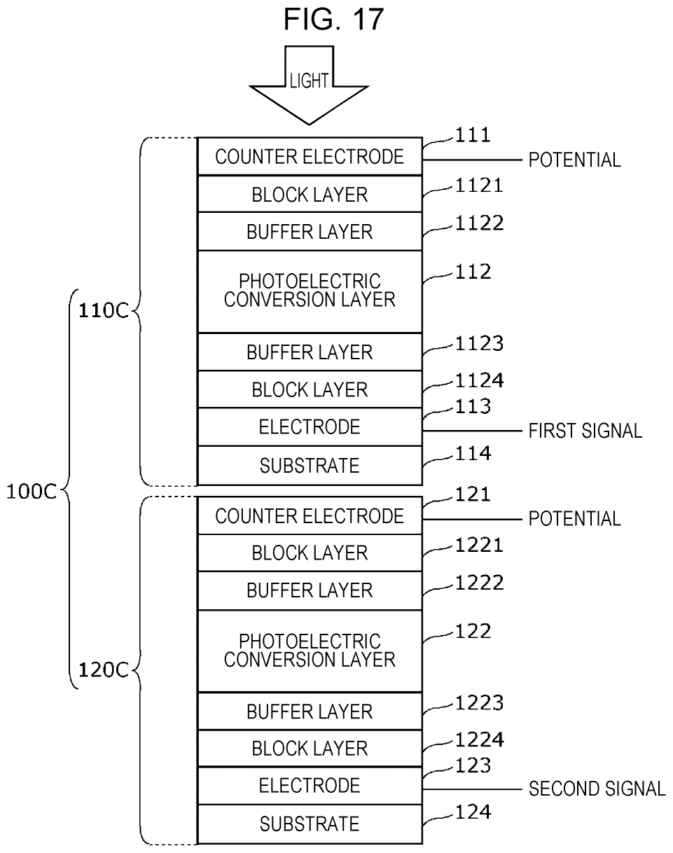

FIG. 17 schematically illustrates a configuration of a multilayer photoelectric converter 100C according to Modification 3. As illustrated in FIG. 17, the multilayer photoelectric converter 100C differs from the multilayer photoelectric converter 100 according to Embodiment 1 in that the multilayer photoelectric converter 100C includes a first photoelectric converter 110C and a second photoelectric converter 120C instead of the first photoelectric converter 110 and the second photoelectric converter 120.

The first photoelectric converter 110C further includes the following components in addition to the components of the first photoelectric converter 110 according to Embodiment 1: a block layer 1121 and a buffer layer 1122, which are located between the counter electrode 111 and the photoelectric conversion layer 112; and a block layer 1124 and a buffer layer 1123, which are located between the electrode 113 and the photoelectric conversion layer 112. The second photoelectric converter 120C further includes the following components in addition to the components of the second photoelectric converter 120 according to Embodiment 1: a block layer 1221 and a buffer layer 1222, which are located between the counter electrode 121 and the photoelectric conversion layer 122; and a block layer 1224 and a buffer layer 1223, which are located between the electrode 123 and the photoelectric conversion layer 122. The block layer 1121, the block layer 1124, the block layer 1221, and the block layer 1224 each correspond to an example of a charge blocking layer.

The block layer 1121 is located between the counter electrode 111 and the buffer layer 1122, and in contact with the counter electrode 111. The block layer 1124 is located between the electrode 113 and the buffer layer 1123, and in contact with the electrode 113. The block layer 1221 is located between the counter electrode 121 and the buffer layer 1222, and in contact with the counter electrode 121. The block layer 1224 is located between the electrode 123 and the buffer layer 1223, and in contact with the electrode 123.

The block layer 1121 and the block layer 1124 each reduce injection of charge from an electrode into the photoelectric conversion layer 112. This makes it possible to reduce noise caused by dark current in the first photoelectric converter 110C. More specifically, the block layer 1121 reduces injection of signal charge from the counter electrode 111 into the photoelectric conversion layer 112. The block layer 1124 reduces injection, from the electrode 113 into the photoelectric conversion layer 112, of charge of the opposite polarity to signal charge. The block layer 1121 serves to transport charge of the opposite polarity to signal charge. The block layer 1124 serves to transport signal charge.

The block layer 1221 and the block layer 1224 each reduce injection of charge from an electrode into the photoelectric conversion layer 122. This makes it possible to reduce noise caused by dark current in the second photoelectric converter 120C. More specifically, the block layer 1221 reduces injection of signal charge from the counter electrode 121 into the photoelectric conversion layer 122. The block layer 1224 reduces injection, from the electrode 123 into the photoelectric conversion layer 122, of charge of the opposite polarity to signal charge. The block layer 1221 serves to transport charge of the opposite polarity to signal charge. The block layer 1224 serves to transport signal charge.

Each of the block layer 1121, the block layer 1124, the block layer 1221, and the block layer 1224 is made of, for example, a semiconductor material with an electron affinity or ionization potential that serves as an energy barrier to reduce injection of the charge mentioned above.

The buffer layer 1122 is located between the photoelectric conversion layer 112 and the block layer 1121, and in contact with the photoelectric conversion layer 112. The buffer layer 1123 is located between the photoelectric conversion layer 112 and the block layer 1124, and in contact with the photoelectric conversion layer 112. The buffer layer 1222 is located between the photoelectric conversion layer 122 and the block layer 1221, and in contact with the photoelectric conversion layer 122. The buffer layer 1223 is located between the photoelectric conversion layer 122 and the block layer 1224, and in contact with the photoelectric conversion layer 122.

The buffer layer 1122 and the buffer layer 1123 each extract charge from the photoelectric conversion layer 112, and transport the charge. This allows for smooth transport of the charge, and consequently improved photoelectric conversion efficiency of the first photoelectric converter 110C. More specifically, the buffer layer 1122 extracts, from the photoelectric conversion layer 112, charge of the opposite polarity to signal charge. The buffer layer 1123 extracts signal charge from the photoelectric conversion layer 112.

The buffer layer 1222 and the buffer layer 1223 each extract charge from the photoelectric conversion layer 122, and transport the charge. This allows for smooth transport of the charge, and consequently improved photoelectric conversion efficiency of the second photoelectric converter 120C. More specifically, the buffer layer 1222 extracts, from the photoelectric conversion layer 122, charge of the opposite polarity to signal charge. The buffer layers 1223 extracts signal charge from the photoelectric conversion layer 122.

Each of the buffer layer 1122, the buffer layer 1123, the buffer layer 1222, and the buffer layer 1223 is made of, for example, a semiconductor material with an electron affinity or ionization potential that allows extraction of the charge mentioned above.

The first photoelectric converter 110C does not have to include all of the block layer 1121, the block layer 1124, the buffer layer 1122, and the buffer layer 1123. Likewise, the second photoelectric converter 120C does not have to include all of the block layer 1221, the block layer 1224, the buffer layer 1222, and the buffer layer 1223. For example, if the first photoelectric converter 110C and the second photoelectric converter 120C are photoconductors, the first photoelectric converter 110C may include neither the block layer 1121 nor the block layer 1124, and the second photoelectric converter 120C may include neither the block layer 1221 nor the block layer 1224.

Embodiment 1, Modification 1 of Embodiment 1, and Modification 2 of Embodiment 1 mentioned above may employ at least one of the first photoelectric converter 110C or the second photoelectric converter 120C.

### EMBODIMENT 2

Embodiment 2 is now described. The following description of Embodiment 2 is directed to a non-contact temperature measurement device employing the multilayer photoelectric converter 100 according to Embodiment 1. The non-contact temperature measurement device according to Embodiment 2 may employ, instead of the multilayer photoelectric converter 100 according to Embodiment 1, the multilayer photoelectric converter according to any one of Modifications 1 to 3 of Embodiment 1 mentioned above. The following description of Embodiment 2 focuses mainly on differences from Embodiment 1, and description of features similar to those in Embodiment 1 is omitted or simplified.

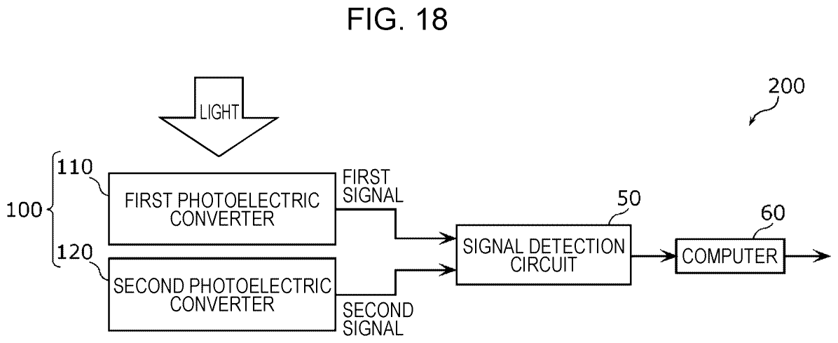

FIG. 18 is a block diagram illustrating a configuration of a non-contact temperature measurement device 200 according to Embodiment 2. As illustrated in FIG. 18, the non-contact temperature measurement device 200 includes the multilayer photoelectric converter 100, a signal detection circuit 50, and a computer 60. The non-contact temperature measurement device 200 detects, for example, thermal radiation emitted from a measured object, which is an object to be measured, and measures temperature based on the detection results. More specifically, light in the form of thermal radiation emitted from the measured object is incident on the multilayer photoelectric converter 100, and the temperature of the measured object is computed based on the first signal and the second signal that are output by the multilayer photoelectric converter 100.

The signal detection circuit 50 detects the first signal output from the first photoelectric converter 110, and the second signal output from the second photoelectric converter 120. In one example, the signal detection circuit 50 includes, for example, a current measurement circuit, and the signal detection circuit 50 detects, as the first signal, a current output from the first photoelectric converter 110, and detects, as the second signal, a current output from the second photoelectric converter 120. In another example, the signal detection circuit 50 may detect, as the first signal, a voltage corresponding to the amount of signal charge collected by the electrode 113, and detect, as the second signal, a voltage corresponding to the amount of signal charge collected by the electrode 123. The signal detection circuit 50 outputs the detected first signal and the detected second signal to the computer 60. The signal detection circuit 50 may, as required, apply analog-digital conversion to the first signal and the second signal before outputting the first signal and the second signal to the computer 60.

The computer 60 computes temperature based on the first signal and the second signal detected by the signal detection circuit 50. The computer 60 computes the temperature of the measured object by the two-color method, based on the first signal and the second signal. For example, the computer 60 outputs the computation results to an external location. The computer 60 may cause the computation results to be displayed on a display (not illustrated). The computer 60 is implemented by, for example, a microcontroller including one or more processors incorporating a program. The function of the computer 60 may be implemented by a combination of a general-purpose processing circuit and software, or may be implemented by hardware dedicated to the processing mentioned above.

A known two-color method may be used as a method for computing temperature by the computer 60. Although computation of temperature is performed by, for example, a method described below, the method for computing temperature is not limited to the method described below as long as temperature can be computed by using the principle of the two-color method.

When thermal radiation from a measured object at a given temperature is incident on the multilayer photoelectric converter 100, the first signal has a magnitude determined by the integral of the following variables over the wavelength: the sensitivity characteristic of the first photoelectric converter 110; the transmittance of light by the first photoelectric converter 110; the black body radiation spectrum at the given temperature; and the emissivity of the measured object. Likewise, when the thermal radiation is incident on the multilayer photoelectric converter 100, the second signal has a magnitude determined by the integral of the following variables over the wavelength: the sensitivity characteristic of the second photoelectric converter 120; the transmittance of light by the second photoelectric converter 120; the black body radiation spectrum at the given temperature; and the emissivity of the measured object.

The sensitivity characteristic of each of the first photoelectric converter 110 and the second photoelectric converter 120 can be measured by, for example, measuring external quantum efficiency with a spectral-sensitivity measurement device or other measurement devices. Likewise, the wavelength dependence of the transmittance of each of the first photoelectric converter 110 and the second photoelectric converter 120 can be determined by the characteristics and thickness of the material used for the multilayer photoelectric converter 100. Accordingly, if the emissivity of the measured object can be regarded as the same or constant, then at the time when thermal radiation from a measured object at a given temperature is incident on the multilayer photoelectric converter 100, the first signal and the second signal have a ratio to each other that is determined by temperature. Therefore, by previously determining the ratio between the first signal and the second signal at each individual temperature, a table, an arithmetic expression, or other information representing the relationship between temperature, and the ratio between the first signal and the second signal can be prepared.

The computer 60 references, for example, a memory storing such a table, an arithmetic expression, or other information representing the relationship between temperature, and the ratio between the first signal and the second signal, and uses the table, the arithmetic expression, or other information to compute temperature based on the first signal and the second signal that have been actually detected by the signal detection circuit 50. In cases such as when the measured object is determined in advance, the ratio between the first signal and the second signal output upon detection of thermal radiation emitted from the measured object at a known temperature may be measured in advance to prepare the table, the arithmetic expression, or other information representing the relationship between temperature, and the ratio between the first signal and the second signal. As described above, the non-contact temperature measurement device 200 according to Embodiment 2 includes the multilayer photoelectric converter 100 mentioned above, and consequently allows for accurate temperature measurement.

### EMBODIMENT 3

Embodiment 3 is described below. The following description of Embodiment 3 is directed to an imaging device employing the multilayer photoelectric converter 100 according to Embodiment 1. The imaging device according to Embodiment 3 may employ, instead of the multilayer photoelectric converter 100 according to Embodiment 1, the multilayer photoelectric converter according to any one of Modifications 1 to 3 of Embodiment 1 mentioned above. The following description of Embodiment 3 focuses mainly on differences from Embodiments 1 and 2, and description of features similar to those in Embodiments 1 and 2 is omitted or simplified.

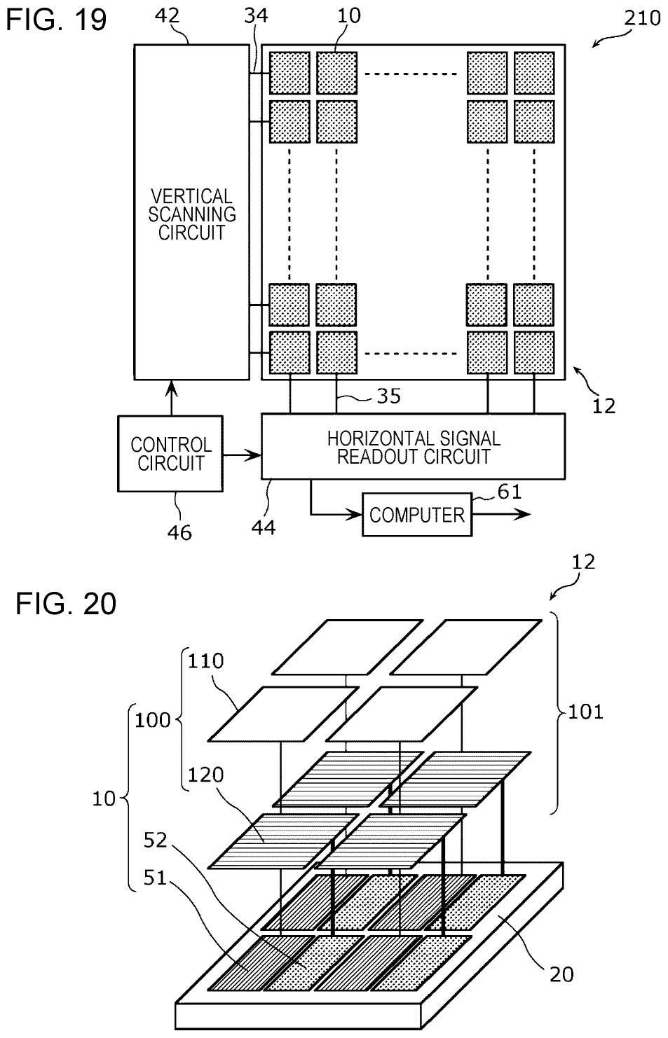

FIG. 19 schematically illustrates a configuration of an imaging device 210 according to Embodiment 3. FIG. 20 schematically illustrates a configuration of a pixel array 12 of the imaging device 210 according to Embodiment 3.

As illustrated in FIG. 19, the imaging device 210 includes the pixel array 12, a vertical scanning circuit 42, a horizontal signal readout circuit 44, a control circuit 46, and a computer 61. The pixel array 12 includes pixels 10. The imaging device 210 captures a temperature image by detecting thermal radiation emitted from a measured object. The imaging device 210 is, for example, a multilayer imaging device.

As illustrated in FIG. 20, the pixel array 12 is provided on a semiconductor substrate 20, and includes a multilayer photoelectric converter array 101 including the multilayer photoelectric converters 100. The pixels 10 each include, for example, the multilayer photoelectric converter 100, a signal detection circuit 51, and a signal detection circuit 52.

In each pixel 10, the signal detection circuit 51 is connected to the first photoelectric converter 110, and detects the first signal output from the first photoelectric converter 110. In each pixel 10, the signal detection circuit 52 is connected to the second photoelectric converter 120, and detects the second signal output from the second photoelectric converter 120. In the example illustrated in FIG. 20, the signal detection circuit 51 and the signal detection circuit 52 are provided in the same plane of the semiconductor substrate 20. The signal detection circuit 51 and the signal detection circuit 52 to be used may be signal detection circuits in known imaging devices including transistors such as a transistor for selecting the pixel 10, a transistor for signal output, and a transistor for signal reset. In another example, the signal detection circuit 51 and the signal detection circuit 52 may be provided in different planes that are vertically separated from each other. In another example, each pixel 10 may include, instead of the signal detection circuit 51 and the signal detection circuit 52 that are individually provided, a single signal detection circuit that detects the first signal and the second signal. In another example, for multiple pixels 10, a single signal detection circuit for detecting the first signal and the second signal from each multilayer photoelectric converter 100 may be provided.

In the example illustrated in FIG. 19, the pixels 10 are arrayed in m rows and n columns. In this example, m and n represent mutually independent integers greater than or equal to 1. The pixels 10 are, for example, arrayed in two dimensions on the semiconductor substrate 20. The multilayer photoelectric converters 100 are also arrayed in two dimensions in a manner similar to how the pixels 10 are arranged. The number and arrangement of the pixels 10, and the number and arrangement of the multilayer photoelectric converters 100 are not limited to those depicted in the drawings. For example, the pixels 10 and the multilayer photoelectric converters 100 may be arrayed in one dimension.

The vertical scanning circuit 42, which is also called a row scanning circuit, is connected with address signal lines 34 provided in correspondence with individual rows of the pixels 10. Signal lines provided in correspondence with individual rows of the pixels 10 are not limited to the address signal lines 34. Alternatively, the vertical scanning circuit 42 may be connected with multiple kinds of signal lines for each row of the pixels 10. Such multiple kinds of signal lines include a signal line connected in correspondence with the signal detection circuit 51, and a signal line connected in correspondence with the signal detection circuit 52. For example, through application of a predetermined voltage to each address signal line 34, the vertical scanning circuit 42 selects the pixels 10 on a row-by-row basis, and performs signal readout and a reset operation.

The horizontal signal readout circuit 44, which is also called a column scanning circuit, is connected with vertical signal lines 35 provided in correspondence with individual columns of the pixels 10. For each of the pixels 10 in a single column, two vertical signal lines 35 may be provided, one in correspondence with the signal detection circuit 51 and the other in correspondence with the signal detection circuit 52. Alternatively, for each of the pixels 10 in a single column, a single vertical signal lines 35 may be provided for the signal detection circuit 51 and the signal detection circuit 52. Signals from the pixels 10 selected on a row-by-row basis by the vertical scanning circuit 42, that is, the first signal output from the first photoelectric converter 110 and the second signal output from the second photoelectric converter 120, are sequentially read out by the horizontal signal readout circuit 44 via the vertical signal lines 35. The horizontal signal readout circuit 44 applies analog-digital conversion (AD conversion) or other processing to the signals read out from the pixels 10. The horizontal signal readout circuit 44 may apply noise-suppressing signal processing, which is typically represented by correlated double sampling, to the signals read out from the pixels 10.

The control circuit 46 controls the overall imaging operation of the imaging device 210 by receiving command data, a clock, or other information given from, for example, a source external to the imaging device 210. The control circuit 46 includes, for example, a timing generator, and supplies drive signals to, for example, the vertical scanning circuit 42 and the horizontal signal readout circuit 44.

Based on the first signal detected by the signal detection circuit 51 and the second signal detected by the signal detection circuit 52, the computer 61 computes a temperature corresponding to the output of each of the multilayer photoelectric converters 100. As with the computer 60 described above, the computer 61 computes the temperature of the measured object by the two-color method, based on the first signal and the second signal. For example, the computer 61 outputs, to an external location, a temperature image representative of the computation results corresponding to each of the multilayer photoelectric converters 100.

As described above, the imaging device 210 includes the multilayer photoelectric converter array made up of the multilayer photoelectric converters 100. Therefore, the imaging device 210 is capable of capturing an accurate temperature image.

The configuration of the imaging device 210 is not limited to the configuration mentioned above. The imaging device 210 may be simply configured to detect the first signal and the second signal output from each multilayer photoelectric converter 100, and compute temperature based on the first signal and the second signal that have been detected. For example, if there are only a few multilayer photoelectric converters 100, the first signal and the second signal from each multilayer photoelectric converter 100 may be output to the computer by, for example, a multiplexer connected to each multilayer photoelectric converter 100.

The multilayer photoelectric converter array 101 included in the imaging device 210 may be used for applications other than imaging devices that capture a temperature image. For example, the multilayer photoelectric converter array 101 can be used for one-dimensional or two-dimensional measurement of the characteristics of a substance.

### OTHER EMBODIMENTS

Although the multilayer photoelectric converter, the multilayer photoelectric converter array, the non-contact temperature measurement device, and the imaging device according to the present disclosure have been described above with reference to their embodiments, the present disclosure is not limited to these embodiments. Various modifications to the above embodiments that may occur to those skilled in the art without departing from the scope and spirit of the present disclosure also fall within the scope of the present disclosure. Constituent elements from multiple embodiments may be combined in any suitable manner without departing from the scope and spirit of the present disclosure.

### Other Remarks

The embodiments of the present disclosure may be modified as exemplified below.
Item 1 provides a multilayer photoelectric converter including:
   an incident surface;
   a first photoelectric converter; and
   a second photoelectric converter,
   in which light is incident on the incident surface from outside of the multilayer photoelectric converter,
   in which the first photoelectric converter is disposed between the incident surface and the second photoelectric converter,
   in which the first photoelectric converter exhibits a first sensitivity characteristic,
   in which the second photoelectric converter exhibits a second sensitivity characteristic,
   in which the first sensitivity characteristic exhibits a local maximum at a wavelength λ1a,
   in which the second sensitivity characteristic exhibits a local maximum at a wavelength λ2a, and
   in which a function f1(λ=λ1a)>a function f2(2=λ2a), and λ1a<λ2a,
      where the function f1(λ) represents the first sensitivity characteristic,
      where the function f2(λ) represents the second sensitivity characteristic, and
      where λ represents wavelength.

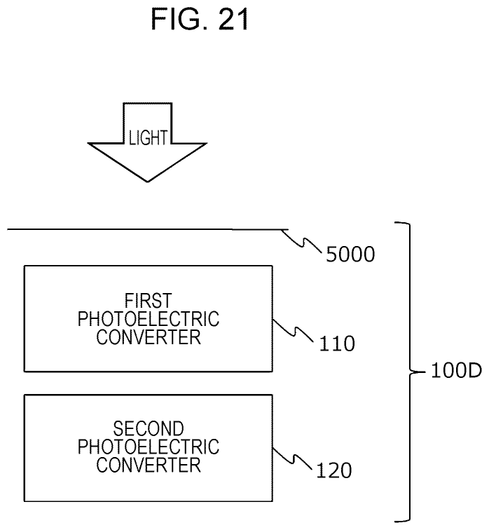

FIG. 21 illustrates the relationship between light incident on the multilayer photoelectric converter, the location of the incident surface, the location of the first photoelectric converter, and the location of the second photoelectric converter.

As illustrated in FIG. 21, a multilayer photoelectric converter 100D includes an incident surface 5000, the first photoelectric converter 110, and the second photoelectric converter 120. Light from outside of the multilayer photoelectric converter 100D is incident on the incident surface 5000. The incident surface 5000 is the surface of a component through which the incoming light from outside of the multilayer photoelectric converter 100D passes. The component is, for example, a protective substrate of a package. The component may be an optical component such as a lens or a filter. The incident surface 5000 may be the surface of the first photoelectric converter 110 itself.

In FIG. 21, the first photoelectric converter 110 may be the first photoelectric converter 110A, and the second photoelectric converter 120 may be the second photoelectric converter 120A.

In FIG. 21, the first photoelectric converter 110 may be the first photoelectric converter 110C, and the second photoelectric converter 120 may be the second photoelectric converter 120C.

The multilayer photoelectric converter 100D may include one or more components that are included in the multilayer photoelectric converter 100, the multilayer photoelectric converter 100A, the multilayer photoelectric converter 100B, and the multilayer photoelectric converter 100C, and/or one or more components that are included in modifications of the multilayer photoelectric converter 100, modifications of the multilayer photoelectric converter 100A, modifications of the multilayer photoelectric converter 100B, and modifications of the multilayer photoelectric converter 100C.
Item 2 provides the multilayer photoelectric converter according to Item 1, in which the second sensitivity characteristic exhibits a cutoff in sensitivity at a wavelength λ2c, and λ2a<λ2c, in which the first sensitivity characteristic exhibits a cutoff in sensitivity at a wavelength λ1c, and λ1a<λ1c, and in which λ1c<λ2c.

The expression “exhibits a cutoff in sensitivity at the wavelength λ1c” may mean that “sensitivity is substantially zero at the wavelength λ1c.”

The expression “sensitivity is substantially zero at the wavelength λ1c” may mean that “at the wavelength λ1c, an electric signal indicative of sensitivity has a value equivalent to the value of noise in an electric-signal processing circuit.”

The expression “sensitivity is substantially zero at the wavelength λ1c” may mean that “relative to the sensitivity at the wavelength λ1a, the sensitivity at the wavelength λ1c is substantially zero.”

An A/D converter included in the signal processing circuit may, upon receiving input of an analog electric signal indicative of the sensitivity at the wavelength λ1c, output information indicative of a value of zero. The information indicative of a value of zero corresponds to the minimum value of information output by the A/D converter.

For example, if the A/D converter has a resolution of 12 bits, and the A/D converter has an input range of zero volts to Vmax volts, the analog electric signal indicative of the sensitivity at the wavelength λ1c may have a value greater than or equal to zero volts and less than or equal to Vmax/2¹² volts.

For example, if the A/D converter has a resolution of 16 bits, and the A/D converter has an input range of zero volts to Vmax volts, the analog electric signal indicative of the sensitivity at the wavelength λ1c may have a value greater than or equal to zero volts and less than or equal to Vmax/216 volts.

The expression “exhibits a cutoff in sensitivity at the wavelength λ2c” may mean that “sensitivity is substantially zero at the wavelength λ2c.”

The expression “sensitivity is substantially zero at the wavelength λ2c” may mean that “at the wavelength λ2c, an electric signal indicative of sensitivity has a value equivalent to the value of noise in the electric-signal processing circuit.”

The expression “sensitivity is substantially zero at the wavelength λ2c” may mean that “relative to the sensitivity at the wavelength λ2a, the sensitivity at the wavelength λ2c is substantially zero.”

The A/D converter included in the signal processing circuit may, upon receiving input of an analog electric signal indicative of the sensitivity at the wavelength λ2c, output information indicative of a value of zero. The information indicative of a value of zero corresponds to the minimum value of information output by the A/D converter.

For example, if the A/D converter has a resolution of 12 bits, and the A/D converter has an input range of zero volts to Vmax volts, the analog electric signal indicative of the sensitivity at the wavelength λ2c may have a value greater than or equal to zero volts and less than or equal to Vmax/2¹² volts.

For example, if the A/D converter has a resolution of 16 bits, and the A/D converter has an input range of zero volts to Vmax volts, the analog electric signal indicative of the sensitivity at the wavelength λ2c may have a value greater than or equal to zero volts and less than or equal to Vmax/216 volts.
Item 3 provides the multilayer photoelectric converter according to Item 2,
   in which the second sensitivity characteristic exhibits a local minimum at a wavelength λxm,
   in which f2(λ2m)<f2(λ2a), and λ2m<λ2a,
   in which in the second sensitivity characteristic, f2(λ2b)=f1(λ1a) at a wavelength λ2b, and
   in which λ2b<λ1a.
Item 4 provides the multilayer photoelectric converter according to Item 3, in which (λ2b+λ2m)/2<λ1a<(λ2m+λ2a)/2.
Item 5 provides the multilayer photoelectric converter according to Item 1,
   in which the first sensitivity characteristic exhibits a cutoff in sensitivity at a wavelength λ1c, and λ1a<λ1c,
   in which the first sensitivity characteristic exhibits a local minimum at a wavelength λ1m, and
   in which f1(Δ1m)<f1(λ1a), and λ1m<λ1a.
Item 5′ provides the multilayer photoelectric converter according to any one of Items 2 to 4,
   in which the first sensitivity characteristic exhibits a local minimum at a wavelength λ1m, and
   in which f1(Δ1m)<f1(λ1a), and λ1m<λ1a.
Item 6 provides the multilayer photoelectric converter according to any one of Items 1 to 4,
   in which each of the first photoelectric converter and the second photoelectric converter is a photodiode or a photoconductor.
Item 7 provides the multilayer photoelectric converter according to any one of Items 1 to 4,
   in which each of the first photoelectric converter and the second photoelectric converter includes
      a first electrode from which a signal is to be output,
      a second electrode located opposite to the first electrode, and
      a photoelectric conversion layer located between the first electrode and the second electrode,
   in which the first electrode included in the first photoelectric converter is a third electrode, the second electrode included in the first photoelectric converter is a fourth electrode, and the photoelectric conversion layer included in the first photoelectric converter is a first photoelectric conversion layer, and
   in which the first electrode included in the second photoelectric converter is a fifth electrode, the second electrode included in the second photoelectric converter is a sixth electrode, and the photoelectric conversion layer included in the second photoelectric converter is a second photoelectric conversion layer.
Item 8 provides the multilayer photoelectric converter according to Item 7,
   in which the fourth electrode is identical to the sixth electrode.
Item 9 provides the multilayer photoelectric converter according to Item 7, further including
   at least one of a first buffer layer, a second buffer layer, a third buffer layer, or a fourth buffer layer,
   in which the first buffer layer is located between the third electrode and the first photoelectric conversion layer,
   in which the second buffer layer is located between the fourth electrode and the first photoelectric conversion layer,
   in which the third buffer layer is located between the fifth electrode and the second photoelectric conversion layer, and
   in which the fourth buffer layer is located between the sixth electrode and the second photoelectric conversion layer.
Item 10 provides the multilayer photoelectric converter according to Item 7, further including
   at least one of a first charge blocking layer, a second charge blocking layer, a third charge blocking layer, or a fourth charge blocking layer,
   in which the first charge blocking layer is located between the third electrode and the first photoelectric conversion layer,
   in which the second charge blocking layer is located between the fourth electrode and the first photoelectric conversion layer,
   in which the third charge blocking layer is located between the fifth electrode and the second photoelectric conversion layer, and
   in which the fourth charge blocking layer is located between the sixth electrode and the second photoelectric conversion layer.
Item 11 provides the multilayer photoelectric converter according to Item 7,
   in which one of the first photoelectric conversion layer or the second photoelectric conversion layer, or each of the first photoelectric conversion layer and the second photoelectric conversion layer includes a quantum dot.
Item 12 provides the multilayer photoelectric converter according to Item 11,
   in which the quantum dot includes at least one of a metal pnictide, a metal chalcogenide, a metal halide, or a metal chalcohalide.
Item 13 provides the multilayer photoelectric converter according to Item 12,
   in which the quantum dot includes the metal chalcogenide, and
   in which the metal chalcogenide is PbS, PbSe, PbTe, CdS, CdSe, CdTe, or HgCdTe.
Item 14 provides the multilayer photoelectric converter according to any one of Items 1 to 4, further including
   a spacer disposed between the first photoelectric converter and the second photoelectric converter to prevent direct contact between the first photoelectric converter and the second photoelectric converter.
Item 15 provides the multilayer photoelectric converter according to Item 14, further including
   an adhesive disposed between the first photoelectric converter and the second photoelectric converter,
   in which the adhesive transmits light at the wavelength λ2a.
Item 16 provides the multilayer photoelectric converter according to any one of Items 1 to 4, further including
   a first long-pass filter disposed between the incident surface and the first photoelectric converter,
   in which λcut1<λ1a, where λcut1 is a cutoff wavelength of the first long-pass filter.
Item 17 provides the multilayer photoelectric converter according to Item 16, further including
   a second long-pass filter located between the first photoelectric converter and the second photoelectric converter,
   in which λ1a<λcut2<λ2a, where λcut2 is a cutoff wavelength of the second long-pass filter.
Item 18 provides the multilayer photoelectric converter according to any one of Items 1 to 4, further including
   a second long-pass filter located between the first photoelectric converter and the second photoelectric converter,
   in which λ1a<λcut2<λ2a, where λcut2 is a cutoff wavelength of the second long-pass filter.

The multilayer photoelectric converter according to the present disclosure, and the multilayer photoelectric converter array according to the present disclosure are applicable to non-contact measurement of the state of a substance by use of different wavelengths of light. In particular, the non-contact temperature measurement device employing the multilayer photoelectric converter according to the present disclosure, and the imaging device employing the multilayer photoelectric converter array according to the present disclosure are applicable to various temperature measurements, such as non-contact temperature measurements using wavelengths from the near-infrared to the mid-infrared regions.

What is claimed is:

1. A multilayer photoelectric converter comprising:
a first photoelectric converter; and
a second photoelectric converter,
wherein the first photoelectric converter and the second photoelectric converter are stacked in this order from a side of the multilayer photoelectric converter where light is incident,
wherein the first photoelectric converter has a sensitivity characteristic with a sensitivity having a peak at a wavelength λ1a,
wherein the second photoelectric converter has a sensitivity characteristic with a sensitivity having a peak at a wavelength λ2a,
wherein a relationship λ1a<λ2a is satisfied, and
wherein the sensitivity of the second photoelectric converter at the wavelength λ2a is less than the sensitivity of the first photoelectric converter at the wavelength λ1a.

2. The multilayer photoelectric converter according to claim 1,
wherein in the sensitivity characteristic of the second photoelectric converter, the sensitivity of the second photoelectric converter has a cutoff at a wavelength λ2c longer than the wavelength λ2a,
wherein in the sensitivity characteristic of the first photoelectric converter, the sensitivity of the first photoelectric converter has a cutoff at a wavelength λ1c longer than the wavelength λ1a, and
wherein a relationship λ1c<λ2c is satisfied.

3. The multilayer photoelectric converter according to claim 2,
wherein in the sensitivity characteristic of the second photoelectric converter,
at wavelengths shorter than the wavelength λ2a, the sensitivity of the second photoelectric converter decreases relative to the sensitivity at the wavelength λ2a and exhibits a local minimum at a wavelength λ2m, and then at wavelengths shorter than the wavelength λ2m, the sensitivity of the second photoelectric converter increases and, at a wavelength λ2b, becomes substantially equal to the sensitivity of the first photoelectric converter at the wavelength λ1a, and
wherein a relationship λ2b<λ1a is satisfied.

4. The multilayer photoelectric converter according to claim 3,
wherein a relationship (λ2b+λ2m)/2<λ1a<(λ2m+λ2a)/2 is satisfied.

5. The multilayer photoelectric converter according to claim 1,
wherein in the sensitivity characteristic of the first photoelectric converter,
the sensitivity of the first photoelectric converter has a cutoff at a wavelength λ1c longer than the wavelength λ1a, and
at wavelengths shorter than the wavelength λ1a, the sensitivity of the first photoelectric converter decreases relative to the sensitivity at the wavelength λ1a and exhibits a local minimum at a wavelength λ1m, and then increases at wavelengths shorter than the wavelength λ1m.

6. The multilayer photoelectric converter according to claim 1,
wherein each of the first photoelectric converter and the second photoelectric converter is a photodiode or a photoconductor.

7. The multilayer photoelectric converter according to claim 1,
wherein each of the first photoelectric converter and the second photoelectric converter includes
a first electrode from which a signal is to be output,
a second electrode located opposite to the first electrode, and
a photoelectric conversion layer located between the first electrode and the second electrode.

8. The multilayer photoelectric converter according to claim 7,
wherein the first photoelectric converter and the second photoelectric converter share the second electrode.

9. The multilayer photoelectric converter according to claim 7,
wherein at least one of the first photoelectric converter or the second photoelectric converter further includes a buffer layer, the buffer layer being located at least one of between the photoelectric conversion layer and the first electrode, or between the photoelectric conversion layer and the second electrode.

10. The multilayer photoelectric converter according to claim 7,
wherein at least one of the first photoelectric converter or the second photoelectric converter further includes a charge blocking layer, the charge blocking layer being located at least one of between the photoelectric conversion layer and the first electrode, or between the photoelectric conversion layer and the second electrode.

11. The multilayer photoelectric converter according to claim 7,
wherein at least one of the first photoelectric converter or the second photoelectric converter includes a quantum dot.

12. The multilayer photoelectric converter according to claim 11,
wherein the quantum dot includes at least one of a metal pnictide, a metal chalcogenide, a metal halide, or a metal chalcohalide.

13. The multilayer photoelectric converter according to claim 12,
wherein the quantum dot includes the metal chalcogenide, and
wherein the metal chalcogenide is PbS, PbSe, PbTe, CdS, CdSe, CdTe, or HgCdTe.

14. The multilayer photoelectric converter according to claim 1,
wherein the first photoelectric converter and the second photoelectric converter are stacked in spaced relation to each other, and
wherein the multilayer photoelectric converter further comprises a retainer that retains a constant gap between the first photoelectric converter and the second photoelectric converter.

15. The multilayer photoelectric converter according to claim 14, further comprising
an adhesive that fills a space between the first photoelectric converter and the second photoelectric converter, and
wherein the adhesive is transmissive of light at the wavelength λ2a.

16. The multilayer photoelectric converter according to claim 1, further comprising
a first long-pass filter located at a side of the first photoelectric converter where the light is incident,
wherein the first long-pass filter has a cutoff wavelength λcut1 shorter than the wavelength λ1a.

17. The multilayer photoelectric converter according to claim 16, further comprising
a second long-pass filter located between the first photoelectric converter and the second photoelectric converter,
wherein the second long-pass filter has a cutoff wavelength λcut2 longer than the wavelength λ1a and shorter than the wavelength λ2a.

18. The multilayer photoelectric converter according to claim 1, further comprising
a second long-pass filter located between the first photoelectric converter and the second photoelectric converter,
wherein the second long-pass filter has a cutoff wavelength λcut2 longer than the wavelength λ1a and shorter than the wavelength λ2a.

19. A multilayer photoelectric converter array comprising a plurality of the multilayer photoelectric converters according to claim 1,
wherein the multilayer photoelectric converters are arrayed one-dimensionally or two-dimensionally.

20. A non-contact temperature measurement device comprising:
the multilayer photoelectric converter according to claim 1;
a signal detection circuit that detects a first signal and a second signal, the first signal being output from the first photoelectric converter, the second signal being output from the second photoelectric converter; and
a computer that, based on the first signal and the second signal detected by the signal detection circuit, computes a temperature.

21. An imaging device that captures a temperature image, the imaging device comprising:
the multilayer photoelectric converter array according to claim 19;
a signal detection circuit that detects a first signal and a second signal, the first signal being output from the first photoelectric converter of each of the multilayer photoelectric converters, the second signal being output from the second photoelectric converter of each of the multilayer photoelectric converters; and
a computer that, based on the first signal and the second signal detected by the signal detection circuit, computes a temperature corresponding to an output of each of the multilayer photoelectric converters.
